(19) United States
(12) Patent Application Publication
(10) Pub. No.: US 2024/0372523 A1
(43) Pub. Date: Nov. 7, 2024

(54) GRATING STRUCTURES FOR SYMMETRIC TRANSVERSELY-EXCITED BULK ACOUSTIC RESONATORS

(71) Applicant: Murata Manufacturing Co., Ltd., Nagaokakyo-shi (JP)

(72) Inventors: Bryant GARCIA, Mississauga (CA); Filip ILIEV, San Francisco, CA (US)

(21) Appl. No.: 18/651,279

(22) Filed: Apr. 30, 2024

Related U.S. Application Data
(60) Provisional application No. 63/499,567, filed on May 2, 2023.

(51) Int. Cl. H03H 9/02; H03H 3/02; H03H 9/13; H03H 9/17; H03H 9/56

(52) U.S. Cl. CPC H03H 9/02118; H03H 3/02; H03H 9/02228; H03H 9/132; H03H 9/173; H03H 9/175; H03H 9/564; H03H 9/568; H03H 2003/021

(57) ABSTRACT

An acoustic resonator device is provided that includes a substrate; a piezoelectric layer having front and back surfaces, with the back surface supported by the substrate; a conductor pattern at the front surface of the piezoelectric layer and including an interdigital transducer (IDT) including a first busbar, a second busbar, and interleaved IDT fingers, with the IDT fingers including a first IDT finger and an nth IDT finger at opposing ends of the IDT; a first grating element that includes a grating bar extending from one of the first busbar or the second busbar, the first grating element being adjacent and parallel to the first IDT finger; a front-side dielectric layer at a front surface of the piezoelectric layer; and a back-side dielectric layer at a back surface of the piezoelectric layer.

### CROSS REFERENCE TO RELATED APPLICATIONS

This application claims priority to U.S. Patent Provisional Application No. 63/499,567, filed May 2, 2023, the entire contents of which are hereby incorporated by reference.

### TECHNICAL FIELD

This disclosure relates to grating structures for transversely-excited film bulk acoustic resonators (XBARs), including grating elements including fingers or grating bars used to achieve lower longitudinal energy leakage in the XBARs.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “passband” of the filter. The range of frequencies stopped by such a filter is referred to as the “stop-band” of the filter. A typical RF filter has at least one passband and at least one stop-band. Specific requirements on a passband or stop-band may depend on the specific application. For example, in some cases a “passband” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact to system performance. Improvements in RF filters can be leveraged to provide system performance improvements, such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate at different frequency bands while also improving the manufacturing processes for making such filters.

The transversely-excited film bulk acoustic resonator (XBAR) is an acoustic resonator structure for use in microwave filters. An XBAR resonator comprises an interdigital transducer (IDT) formed on a thin floating layer, or diaphragm, of a single-crystal piezoelectric material. The IDT includes a first set of parallel fingers, extending from a first busbar and a second set of parallel fingers extending from a second busbar. The first and second sets of parallel fingers are interleaved. A microwave signal applied to the IDT excites a shear primary acoustic wave in the piezoelectric diaphragm. XBAR resonators provide very high electromechanical coupling and high frequency capability. XBAR resonators may be used in a variety of RF filters including band-reject filters, bandpass filters, duplexers, and multiplexers. XBARs are well suited for use in filters for communications bands with frequencies above 3 GHz.

However, in order to provide the type of high-level performance required by the above-described communications applications, potential loss mechanisms that detract from the performance of the XBAR structure may need to be addressed. One such loss mechanism is leakage of acoustic energy out of the XBAR structure.

### SUMMARY

Accordingly, grating structures that reduce the acoustic energy leakage in the longitudinal direction at the ends of an XBAR may improve the performance of XBAR devices and, by extension, improve the performance of the filters that include such devices.

Aspects of the disclosure includes an acoustic resonator device that includes a substrate, a piezoelectric layer having front and back surfaces, a front-side dielectric layer at the front surface of the piezoelectric layer, a back-side dielectric layer at the back surface of the piezoelectric layer that couples the substrate to the back surface of the piezoelectric layer, a conductor pattern at the front surface of the piezoelectric layer, and a first grating element comprising a grating bar extending from one of the first busbar or the second busbar. The first grating element is adjacent and parallel to the first IDT finger. The conductor pattern includes an interdigital transducer (IDT) including a first busbar, a second busbar, and interleaved IDT fingers that include a first IDT finger and an nth IDT finger at opposing ends of the IDT. In an aspect, an acoustic thickness of the back-side dielectric layer is between 0.5 times an acoustic thickness of the front-side dielectric layer and 1.5 times the acoustic thickness of the front-side dielectric layer.

In an example, a thickness of the front-side dielectric layer is larger than or equal to a thickness of the IDT fingers.

In an example, a distance between the grating bar and the first IDT finger is larger than or equal to 0.8×pIDT and is less than 1.0×pIDT where pIDT is a pitch of the IDT fingers. The distance is measured in a direction that is perpendicular to the IDT fingers and parallel to a surface of the substrate.

In an example, a width of the grating bar is in a range defined by 0.8 μm and 1.2 μm, and the width is measured in a direction that is perpendicular to the IDT fingers and parallel to a surface of the substrate.

In an example, the acoustic resonator device further includes a second grating element comprising a second grating bar extending from one of the first busbar or the second busbar. The second grating bar is adjacent and parallel to the nth IDT finger.

In an example, a width of the second grating bar is in a range defined by 0.8 μm and 1.2 μm, the width is measured in a first direction that is perpendicular to the IDT fingers and parallel to a surface of the substrate, and a distance between the second grating bar and the nth IDT finger is larger than or equal to 0.8×pIDT and less than 1.0×pIDT. pIDT is a pitch of the IDT fingers, and the distance is measured in the first direction.

In an example, the grating bar of the first grating element is connected to a same one of the first busbar or the second busbar as the first IDT finger, and the second grating bar of the second grating element is connected to a same one of the first busbar or the second busbar as the nth IDT finger.

In an example, the piezoelectric layer and the IDT are configured such that a radio frequency signal applied to the IDT excites a primary shear acoustic wave in the piezoelectric layer.

An aspect of the disclosure includes an acoustic resonator device. The acoustic resonator device includes a substrate, a piezoelectric layer having front and back surfaces, a front-side dielectric layer at the front surface of the piezoelectric layer, a back-side dielectric layer at the back surface of the piezoelectric layer that couples the substrate to the back surface of the piezoelectric layer, a conductor pattern at the front surface of the piezoelectric layer, and a first grating element. The conductor pattern includes an interdigital transducer (IDT) including a first busbar, a second busbar, and interleaved IDT fingers that include a first IDT finger and an nth IDT finger at opposing ends of the IDT. The first grating element includes a finger extending from one of the first busbar or the second busbar. The first grating element is adjacent and parallel to the first IDT finger. A width of the finger of the first grating element is less than 0.5 μm, and the width is measured in a direction that is perpendicular to the IDT fingers. An acoustic thickness of the back-side dielectric layer is between 0.5 times an acoustic thickness of the front-side dielectric layer and 1.5 times the acoustic thickness of the front-side dielectric layer.

In an example, a thickness of the front-side dielectric layer is larger than or equal to a thickness of the IDT fingers.

In an example, the first grating element includes two fingers, a first of the two fingers of the first grating element is located adjacent to the first IDT finger, and a second of the two fingers of the first grating element is located on an opposite side of the first of the two fingers of the first grating element with respect to the first IDT finger.

In an example, a pitch of the two fingers of the first grating element is in a range defined by 0.8×pIDT and 1.5×pIDT where pIDT is a pitch of the IDT fingers.

In an example, the acoustic resonator device further includes a second grating element comprising a finger extending from one of the first busbar or the second busbar. The second grating element is adjacent and parallel to the nth IDT finger.

In an example, the second grating element comprises two fingers, a first of the two fingers of the second grating element is located adjacent to the nth IDT finger, and a second of the two fingers of the second grating element is located on an opposite side of the first of the two fingers of the second grating element with respect to the nth IDT finger.

In an example, the finger of the first grating element is connected to a same one of the first busbar or the second busbar as the first IDT finger, and the finger of the second grating element is connected to a same one of the first busbar or the second busbar as the nth IDT finger.

In an example, the piezoelectric layer and the IDT are configured such that a radio frequency signal applied to the IDT excites a shear primary acoustic wave within the piezoelectric layer.

An aspect of the disclosure includes a bandpass filter. The bandpass filter includes a plurality of acoustic resonators comprising one or more series resonators and one or more shunt resonators. In an example, each of the plurality of acoustic resonators includes a diaphragm comprising a portion a piezoelectric layer that is over a cavity of the respective acoustic resonator, and an interdigital transducer (IDT) at a surface of the piezoelectric layer. The IDT may include a first busbar, a second busbar, and interleaved IDT fingers disposed at the respective diaphragm. The IDT fingers include a first IDT finger and an nth IDT finger at opposing ends of the IDT. At least one of the one or more shunt resonators may further include a first grating element comprising a grating bar extending from one of the first busbar or the second busbar, a front-side dielectric layer on a front surface of the piezoelectric layer, a back-side dielectric layer on a back surface of the piezoelectric layer. The first grating element is adjacent and parallel to the first IDT finger. An acoustic thickness of the back-side dielectric layer is between 0.5 times an acoustic thickness of the front-side dielectric layer and 1.5 times the acoustic thickness of the front-side dielectric layer.

In an example, a distance between the grating bar and the first IDT finger is larger than or equal to 0.8×pIDT and less than 1.0×pIDT where pIDT is a pitch of the IDT fingers. The distance is measured in a first direction that is perpendicular to a direction in which the IDT fingers extends. A width of the grating bar is in a range defined by 0.8 μm and 1.2 μm, and the width is measured in the first direction.

In an example, the at least one of the one or more shunt resonators further comprises a second grating element that includes a second grating bar extending from one of the first busbar or the second busbar. The second grating bar is adjacent and parallel to the nth IDT finger.

In an example, a width of the second grating bar is in a range defined by 0.8 μm and 1.2 μm, and the width is measured in a first direction that is perpendicular to the IDT fingers and parallel to a surface of the diaphragm. A distance between the second grating bar and the nth IDT finger is larger than or equal to 0.8×pIDT and less than 1.0×pIDT, pIDT is a pitch of the IDT fingers, and the distance is measured in the first direction.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIG. 1A includes a schematic plan view and two schematic cross-sectional views of a transversely-excited film bulk acoustic resonator (XBAR).

FIG. 1B shows a schematic cross-sectional view of an alternative configuration of an XBAR.

FIG. 2A is an expanded schematic cross-sectional view of a portion of the XBAR of FIG. 1A.

FIG. 2B is an expanded schematic cross-sectional view of an alternative configuration of the XBAR of FIG. 1A.

FIG. 2C is an expanded schematic cross-sectional view of another alternative configuration of the XBAR of FIG. 1A.

FIG. 2D is an expanded schematic cross-sectional view of another alternative configuration of the XBAR of FIG. 1A.

FIG. 2E is an expanded schematic cross-sectional view of a portion of a solidly-mounted XBAR (SM XBAR).

FIG. 3A is a schematic cross-sectional view of an XBAR according to an exemplary aspect.

FIG. 3B is an alternative schematic cross-sectional view of an XBAR according to an exemplary aspect.

FIG. 4 is a graphic illustrating a shear horizontal acoustic mode in an XBAR.

FIG. 5A is a schematic block diagram of a filter using XBARs of FIGS. 1A and/or 1B.

FIG. 5B is a schematic diagram of a radio frequency module that includes an acoustic wave filter device according to an exemplary aspect.

FIG. 6 is a schematic cross-sectional view of two XBARs illustrating a frequency-setting dielectric layer.

FIG. 7 is a cross-section view of a symmetrical XBAR (SXBAR) with embedded IDT fingers on the front surface of a piezoelectric diaphragm and a continuous dielectric layer on the back surface of the diaphragm.

FIG. 8 is a graphic simulation that compares the ideal performance of an XBAR, such as an SXBAR, with the actual performance of an XBAR having a similar structure but having no grating structure.

FIG. 9 is a graphical simulation that compares the ideal performance of an XBAR, such as an SXBAR, with performance of XBARs, such as SXBARs, having related resonator grating structures.

FIG. 10 is a schematic top view of an IDT in an SXBAR with grating elements of one aspect.

FIG. 11 is a graph showing a simulation illustrating the minimum BodeQ and the median BodeQ of an SXBAR structure having the grating elements shown in FIG. 10, at different grating mark dimensions.

FIG. 12 is a graph showing a simulation that compares the ideal performance of an SXBAR with performance of an SXBAR structure having the grating elements shown in FIG. 10 at a grating mark of 0.1 μm.

FIG. 13 is a graph showing a simulation illustrating the minimum BodeQ and the median BodeQ of an SXBAR structure having the grating elements shown in FIG. 10, at different pitch dimensions.

FIG. 14 is a schematic plan view of an IDT in an SXBAR with grating elements of another aspect.

FIGS. 15A and 15B are heat map style graphs showing minimum BodeQ and mean BodeQ, respectively, of an SXBAR having the grating element shown in FIG. 14, at different distances from an edge IDT finger and at different mark dimensions.

FIGS. 16A and 16B are heat map style graph showing performance of an SXBAR having the grating element shown in FIG. 14, at different distances from an edge IDT finger, different ratios of the distance from the edge IDT finger to the pitch of the IDT fingers, and at different mark dimensions.

FIG. 17 compares simulated performance of two SXBARs.

FIG. 18 is a flow chart of a method for fabricating an XBAR or a filter using XBARs.

Throughout this description, elements appearing in figures are assigned three-digit or four-digit reference designators, where the two least significant digits are specific to the element and the one or two most significant digits are the figure number where the element is first introduced. An element that is not described in conjunction with a figure may be presumed to have the same characteristics and function as a previously described element having the same reference designator.

### DETAILED DESCRIPTION

Various aspects of the disclosed bulk acoustic resonator, a filter device, a radio frequency module, and method of manufacturing the same are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

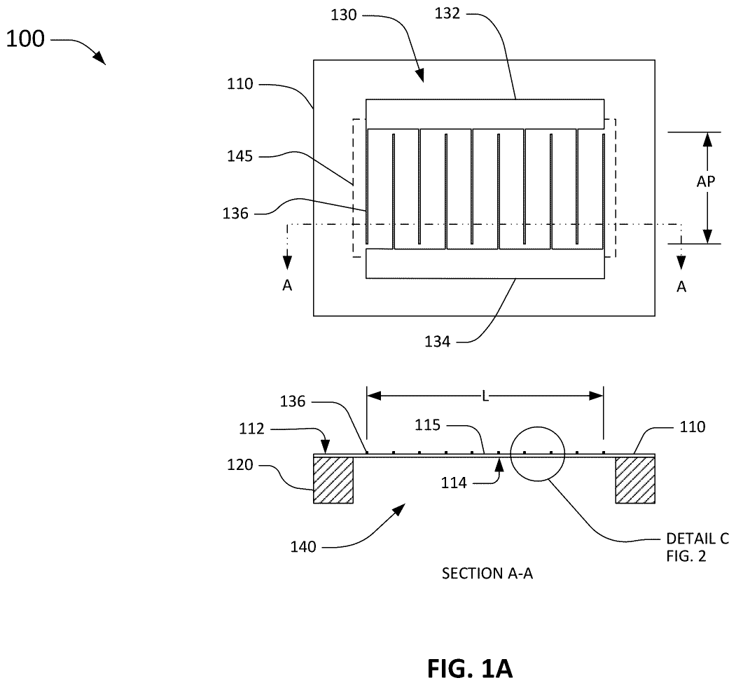

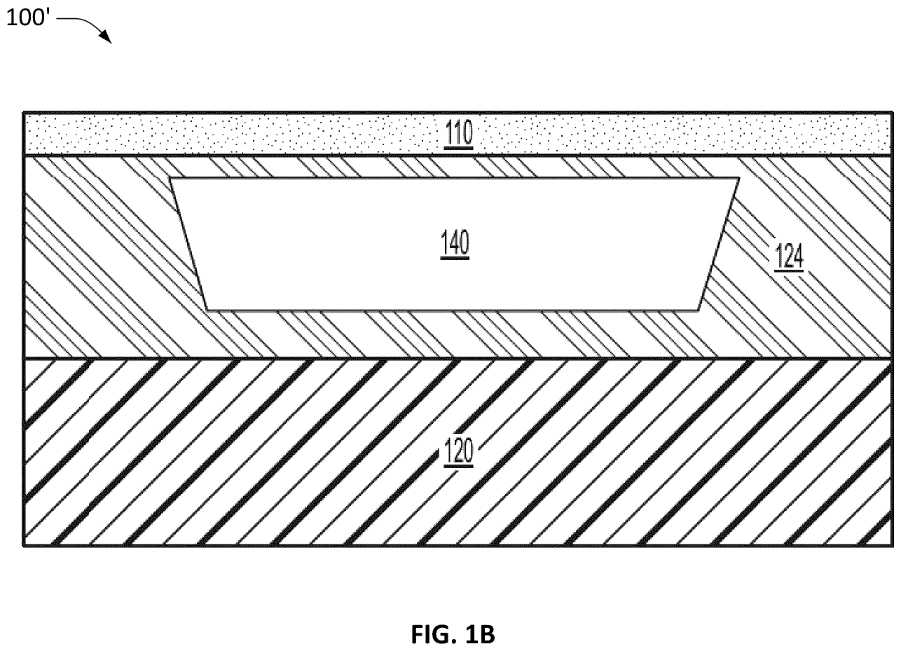

FIG. 1A shows a simplified schematic top view and orthogonal cross-sectional views of a bulk acoustic resonator device, namely a transversely excited film bulk acoustic resonator (XBAR) 100. XBAR resonators, such as the resonator 100, may be used in a variety of RF filters including band-rejection filters, bandpass filters, duplexers, and multiplexers. XBARs are particularly suited for use in filters for communications bands with frequencies above 3 GHz.

In general, the XBAR 100 is made up of a thin film conductor pattern formed at one or both surfaces of a piezoelectric layer 110 (herein piezoelectric plate or piezoelectric layer may be used interchangeably) having parallel front side 112 and a back side 114, respectively (also referred to generally first and second surfaces, respectively). It should be appreciated that the term “parallel” generally refers to the front side 112 and back side 114 being opposing to each other and that the surfaces are not necessarily planar and parallel to each other. For example, to the manufacturing variances result from the deposition process, the front side 112 and back side 114 may have undulations of the surface as would be appreciated to one skilled in the art. Moreover, the term “substantially” as used herein is used to describe when components, parameters and the like are generally the same (i.e., “substantially constant”), but it takes into account minor variations resulting from manufacturing variances, for example. For example, the “unit pitch” as described below between respective finger units of the IDT is described as being “substantially constant” across the length of the IDT. For purposes of this disclosure, this means that the unit pitch of the IDT is designed to be constant based on the configured manufacturing and metal patterning processes used to form the IDT fingers of the exemplary aspects, but may vary slightly (e.g., within an acceptable threshold or percentage) in practice due to possible manufacturing variances as would be appreciated to one skilled in the art.

According to an exemplary aspect, the piezoelectric layer is a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, XBARs may be fabricated on piezoelectric layers with other crystallographic orientations including rotated Z-cut, Z-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0°] is commonly referred to as “120° rotated Y-cut” or “120Y.” Thus, the Euler angles for 120YX and 128YX are (0, 120-90,0) and (0, 128-90,0) respectively. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be at least partially supported by a surface of the substrate 120 except for a portion of the piezoelectric layer 110 that forms a diaphragm 115 that is over (e.g., spanning or extending over) a cavity 140 in one or more layers below the piezoelectric layer 110 such as one or more intermediate layers above or in the substrate. In other words, the back side 114 of the piezoelectric layer 110 can be coupled or connected either directly or indirectly, via one or more intermediate layers (e.g., a dielectric layer), to a surface of the substrate 120. Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 115 due to its physical resemblance to the diaphragm of a microphone. As shown in FIG. 1A, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

According to the exemplary aspect, the substrate 120 is configured to provide mechanical support to the piezoelectric layer 110. The substrate 120 may be, for example, silicon, sapphire, quartz, or some other material or combination of materials. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

For purposes of this disclosure, “cavity” has its conventional meaning of “an empty space within a solid body.” The cavity 140 may be a hole completely through the substrate 120 (as shown in Section A-A), a hole within a dielectric layer (as shown in FIG. 1B), or a recess in the substrate 120. The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other. At least a portion of the interleaved fingers overlap for a distance AP, commonly referred to as the “aperture” of the IDT. The center-to-center distance L between the outermost fingers of the IDT 130 is the “length” of the IDT.

In the example of FIG. 1A, the IDT 130 is at the surface of the front side 112 (e.g., the first surface) of the piezoelectric layer 110. However, as discussed below, in other configurations, the IDT 130 may be at the surface of the back side 114 (e.g., the second surface) of the piezoelectric layer 110 or at both the surfaces of the front and back sides 112, 114 of the piezoelectric layer 110, respectively.

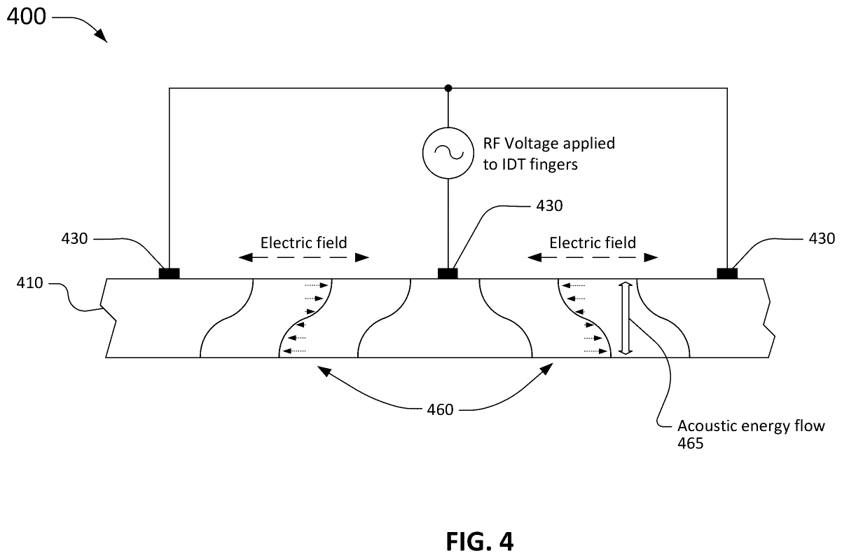

The first and second busbars 132, 134 are configured as the terminals of the XBAR 100. In operation, a radio frequency signal or microwave signal applied between the two busbars 132, 134 of the IDT 130 primarily excites an acoustic mode (i.e., a primarily shear acoustic mode) within the piezoelectric layer 110. As will be discussed in further detail, the primarily excited shear acoustic mode is a bulk shear mode or bulk acoustic wave where acoustic energy of a bulk shear acoustic wave is excited in the piezoelectric layer 110 by the IDT 130 and propagates along a direction substantially, predominantly, and/or primarily orthogonal to the surface of the piezoelectric layer 110, which is also primarily normal, or transverse, to the direction of the electric field created by the IDT fingers. That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIG. 4

For purposes of this disclosure, “primarily acoustic mode” may generally refer to an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely excited film bulk wave resonator. One physical constraint is that when the radio frequency or microwave signal is applied between the two busbars 132, 134 of the IDT 130, heat is generated that must be dissipated from the resonator for improved performance. In general, heat can be dissipated by lateral conduction on the membrane (e.g., in the electrodes themselves), and vertical conduction through a cavity to substrate.

In any event, the IDT 130 is positioned at or on the piezoelectric layer 110 such that at least the fingers of the IDT extend at or on the portion of the piezoelectric layer 110 that is over the cavity 140, for example, the diaphragm 115 as described herein. As shown in FIG. 1A, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved.

According to an exemplary aspect, the area of XBAR 100 is determined as the area of the IDT 130. For example, the area of the IDT 130 can be determined based on the measurement of the length L multiplied by the width of the aperture AP of the interleaved fingers of the IDT 130. As used herein through the disclosure, area is referenced in μm². Thus, the area of the XBAR 100 may be adjusted based on design choices, as described below, thereby adjusting the overall capacitance of the XBAR 100.

For ease of presentation in FIG. 1A, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

FIG. 1B shows a schematic cross-sectional view of an alternative XBAR configuration 100′. In FIG. 1B, the cavity 140 (which can correspond generally to cavity 140 of FIG. 1A) of the resonator 100′ is formed entirely within a dielectric layer 124 (for example SiO₂, as in FIG. 1B) that is located between the substrate 120 (indicated as Si in FIG. 1B) and the piezoelectric layer 110 (indicated as LN in FIG. 1B). Although a single dielectric layer 124 is shown having cavity 140 formed therein (e.g., by etching), it should be appreciated that the dielectric layer 124 can be formed by a plurality of separate dielectric layers formed on each other.

Moreover, in the example of FIG. 1B, the cavity 140 is defined on all sides by the dielectric layer 124. However, in other exemplary embodiments, one or more sides of the cavity 140 may be defined by the substrate 120 or the piezoelectric layer 110. In the example of FIG. 1B, the cavity 140 has a trapezoidal shape. However, as noted above, cavity shape is not limited and may be rectangular, oval, or other shapes.

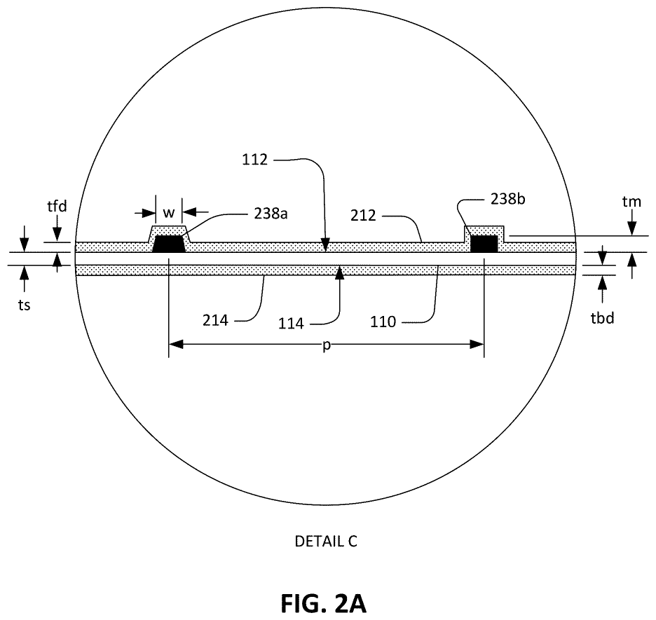

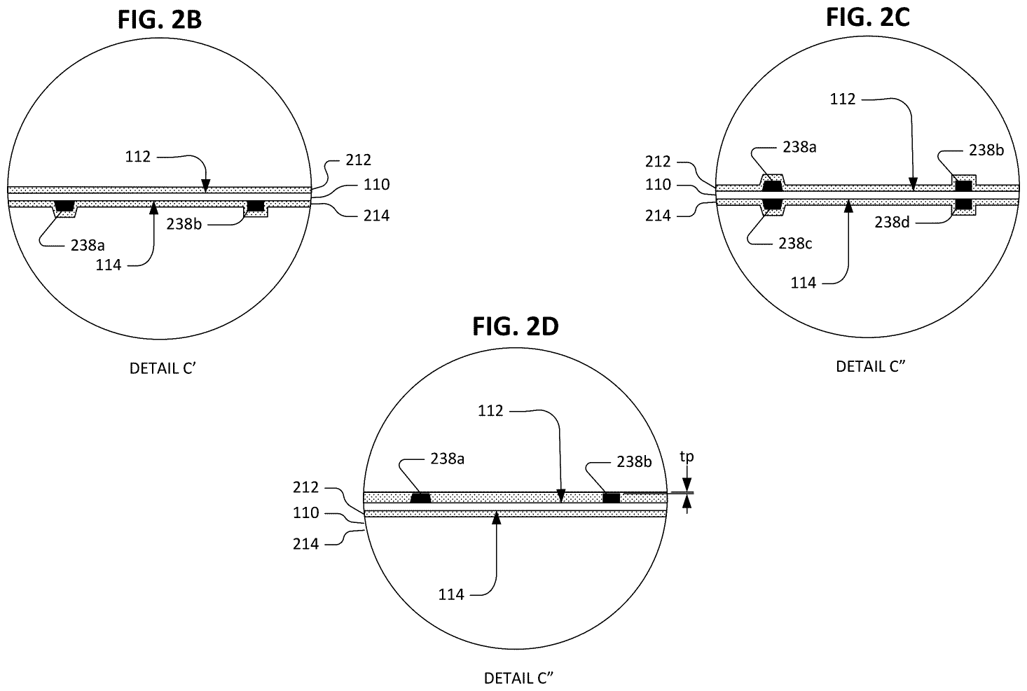

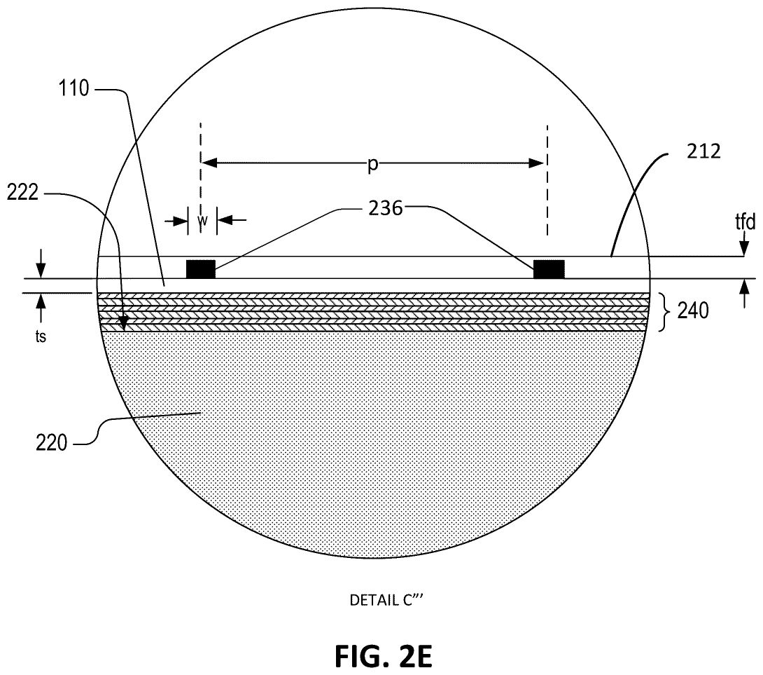

FIG. 2A shows a detailed schematic cross-sectional view of the XBAR 100 of FIG. 1A or 1B. The piezoelectric layer 110 is a single-crystal layer of piezoelectrical material having a thickness ts. ts may be, for example, 100 nm to 1500 nm. When used in filters for 5G NR and Wi-Fi™ bands from 3.4 GHZ to 7 GHZ, the thickness ts may be, for example, 150 nm to 500 nm.

In this aspect, a front side dielectric layer 212 (e.g., a first dielectric coating layer or material) can be formed on the front side 112 of the piezoelectric layer 110. The “front side” of the XBAR is, by definition, the surface facing away from the substrate. The front side dielectric layer 212 has a thickness tfd. As shown in FIG. 2A the front side dielectric layer 212 covers the IDT fingers 238a, 238b, which can correspond to fingers 136 as described above with respect to FIG. 1A. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back side dielectric layer 214 (e.g., a second dielectric coating layer or material) can also be formed on the back side of the back side 114 of the piezoelectric layer 110. In general, for purposes of this disclosure, the term “back side” means on a side opposite the conductor pattern of the IDT structure and/or opposite the front side dielectric layer 212. Moreover, the back side dielectric layer 214 has a thickness tbd. The front side and back side dielectric layers 212, 214 may be a non-piezoelectric dielectric material, such as silicon dioxide or silicon nitride. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. Either or both of the front side and back side dielectric layers 212, 214 may be formed of multiple layers of two or more materials according to various exemplary aspects.

The IDT fingers 238a, 238b may be aluminum, substantially (i.e., predominantly) aluminum alloys, copper, substantially (i.e., predominantly) copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1A) of the IDT may be made of the same or different materials as the fingers. The cross-sectional shape of the IDT fingers may be trapezoidal (finger 238a), rectangular (finger 238b) or some other shape in various exemplary aspects.

Dimension p is the center-to-center spacing between adjacent IDT fingers, such as the IDT fingers 238a, 238b in FIGS. 2A-2C. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along AP, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar. The center-to-center spacing may be constant over the length of the IDT, in which case the dimension p may be referred to as the pitch of the IDT and/or the pitch of the XBAR. However, according to an exemplary aspect as will be discussed in more detail below, the center-to-center spacing varies along the length of the IDT, in which case the pitch of the IDT may be the average value of dimension p over the length of the IDT. Center-to-center spacing from one finger to an adjacent finger may vary continuously when compared to other adjacent fingers, in discrete sections of multiple adjacent pairs, or any combination thereof. Each IDT finger, such as the IDT fingers 238a, 238b in FIGS. 2A, 2B, and 2C, has a width w measured normal to the long direction of each finger. The width w may also be referred to herein as the “mark.” In general, the width of the IDT fingers may be constant over the length of the IDT, in which case the dimension w may be the width of each IDT finger. However, in an exemplary aspect as will be discussed below, the width of individual IDT fingers varies along the length of the IDT 130, in which case dimension w may be the average value of the widths of the IDT fingers over the length of the IDT. Note that the pitch p and the width w of the IDT fingers are measured in a direction parallel to the length L of the IDT, as defined in FIG. 1A.

In general, the IDT of an XBAR differs substantially from the IDTs used in surface acoustic wave (SAW) resonators, primarily in that IDTs of an XBAR excite a primary shear acoustic mode (also referred to as a primary shear mode, a primary shear thickness mode, or the like), as described in more detail below with respect to FIG. 4, where SAW resonators excite a surface wave in operation. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. In addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1A) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front side and back side dielectric layers 212, 214 disposed thereon. In an exemplary aspect, the thickness of one or both dielectric layers can be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tfd of the front side dielectric layer 212 over the IDT fingers 238a, 238b may be greater than or equal to a minimum thickness required to deal and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back side dielectric layer 214 may be configured to a specific thickness to adjust the resonance frequency of the resonator as will be described in more detail below.

Although FIG. 2A discloses a configuration in which IDT fingers 238a and 238b are at the front side 112 of the piezoelectric layer 110, alternative configurations can be provided. For example, FIG. 2B shows an alternative configuration in which the IDT fingers 238a, 238b are at the back side 114 of the piezoelectric layer 110 (i.e., facing the cavity) and are covered by a back side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b at the back side 114 of the piezoelectric layer 110 as shown in FIG. 2B may eliminate addressing both the change in frequency as well as the effect it has on spurs as compared when the IDT fingers 238a and 238b are on the front side 112 of the piezoelectric layer 110.

FIG. 2C shows an alternative configuration in which IDT fingers 238a, 238b are on the front side 112 of the piezoelectric layer 110 and are covered by a front side dielectric layer 212. IDT fingers 238c, 238d are also on the back side 114 of the piezoelectric layer 110 and are also covered by a back side dielectric layer 214. As previously described, the front side and back side dielectric layer 212, 214 are not necessarily the same thickness or the same material.

FIG. 2D shows another alternative configuration in which IDT fingers 238a, 238b are on the front side 112 of the piezoelectric layer 110 and are covered by a front side dielectric layer 212. The surface of the front side dielectric layer is planarized. The front side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

Each of the XBAR configurations described above with respect to FIGS. 2A to 2D include a diaphragm spanning over a cavity. However, in an alternative aspect, the bulk acoustic resonator can be solidly mounted in which the diaphragm with IDT fingers is mounted on or above an acoustic mirror, such as a Bragg mirror, which in turn can be mounted on a substrate.

In particular, FIG. 2E shows a detailed schematic cross-sectional view of a solidly mounted XBAR (SM XBAR). The SM XBAR includes a piezoelectric layer 110 and an IDT (of which only two fingers 236 are visible) with a dielectric layer 212 disposed on the piezoelectric layer 110 and IDT fingers 236. The piezoelectric layer 110 has parallel front and back surfaces similar to the configurations described above. Dimension ts is the thickness of the piezoelectric layer 110. The width of the IDT fingers 236 is dimension w, thickness of the IDT fingers is dimension tm, and the IDT pitch is dimension p.

In contrast to the XBAR devices shown in FIG. 1A, the IDT of an SM XBAR in FIG. 2E is not formed on a diaphragm spanning a cavity in the substrate. Instead, an acoustic Bragg reflector 240 is sandwiched between a surface 222 of the substrate 220 and the back surface of the piezoelectric layer 110. The term “sandwiched” means the acoustic Bragg reflector 240 is both disposed between and mechanically attached to a surface 222 of the substrate 220 and the back surface of the piezoelectric layer 110. In some circumstances, layers of additional materials may be disposed between the acoustic Bragg reflector 240 and the surface 222 of the substrate 220 and/or between the Bragg reflector 240 and the back surface of the piezoelectric layer 110. Such additional material layers may be present, for example, to facilitate bonding the piezoelectric layer 110, the acoustic Bragg reflector 240, and the substrate 220.

The acoustic Bragg reflector 240 may be an acoustic mirror configured to reflect at least a portion of the primary acoustic mode excited in the piezoelectric and includes multiple dielectric layers that alternate between materials having high acoustic impedance and materials having low acoustic impedance. The acoustic impedance of a material is the product of the material's shear wave velocity and density. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As discussed above, the primary acoustic mode in the piezoelectric layer of an XBAR is a shear bulk wave. In an exemplary aspect, each layer of the acoustic Bragg reflector 240 has a thickness equal to, or about, one-fourth of the wavelength in the layer of a shear bulk wave having the same polarization as the primary acoustic mode at or near a resonance frequency of the SM XBAR. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide. All of the high acoustic impedance layers of the acoustic Bragg reflector 240 are not necessarily the same material, and all of the low acoustic impedance layers are not necessarily the same material. In the example of FIG. 2E, the acoustic Bragg reflector 240 has a total of six layers, but an acoustic Bragg reflector may have more than, or less than, six layers in alternative configurations.

The IDT fingers, such as IDT finger 236, 238a, and 238b, may be disposed on a surface of the front side 112 of the piezoelectric layer 110. Alternatively, IDT fingers, such as IDT finger 236, 238a, and 238b, may be disposed in grooves formed in the surface of the front side 112. The grooves may extend partially through the piezoelectric layer. Alternatively, the grooves may extend completely through the piezoelectric layer.

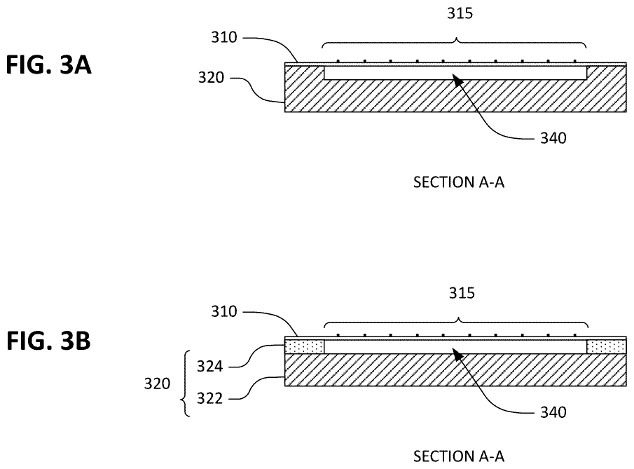

FIG. 3A and FIG. 3B show two exemplary cross-sectional views along the section plane A-A defined in FIG. 1A of XBAR 100. In FIG. 3A, a piezoelectric layer 310, which corresponds to piezoelectric layer 110, is attached directly to a substrate 320, which can correspond to substrate 120 of FIG. 1A. Moreover, a cavity 340, which does not fully penetrate the substrate 320, is formed in the substrate under the portion (i.e., the diaphragm 315) of the piezoelectric layer 310 containing the IDT of an XBAR. The cavity 340 can correspond to cavity 140 of FIGS. 1A and/or 1B in an exemplary aspect. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. For example, the base 322 may be silicon (e.g., a silicon support substrate) and the intermediate layer 324 may be silicon dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324 under the portion (i.e., the diaphragm 315) of the piezoelectric layer 310 containing the IDT fingers of an XBAR. The cavity 340 may be formed, for example, by etching the intermediate layer 324 before attaching the piezoelectric layer 310. Alternatively, the cavity 340 may be formed by etching the intermediate layer 324. In other example embodiments, the cavity 340 may be defined in the intermediate layer 324 by other means from whether the intermediate layer 324 was etched to define the cavity 340. In some cases, the etching may be performed with a selective etchant that reaches the substrate through one or more openings (not shown) provided in the piezoelectric layer 310.

In this case, the diaphragm 315, which can correspond to diaphragm 115 of FIG. 1A, for example, in an exemplary aspect, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may partially extend into, but not entirely through the intermediate layer 324 (i.e., the intermediate layer 324 may extend over the bottom of the cavity on top of the base 322) or may extend through the intermediate layer 324 and into (either partially or wholly) the base 322. As described above, it should be appreciated that the interleaved fingers of the IDT can be disposed on either or both surfaces of the diaphragm 315 in FIGS. 3A and 3B according to various exemplary aspects.

FIG. 4 is a graphical illustration of the primarily excited acoustic mode of interest in an XBAR. FIG. 4 shows a small portion of an XBAR 400 including a piezoelectric layer 410 and three interleaved IDT fingers 430. In general, the exemplary configuration of XBAR 400 can correspond to any of the configurations described above and shown in FIGS. 2A to 2D according to an exemplary aspect. Thus, it should be appreciated that piezoelectric layer 410 can correspond to piezoelectric layer 110 and IDT fingers 430 can be implemented according to any of the configurations of fingers 238a and 238b, for example.

In operation, an RF voltage is applied to the interleaved fingers 430. This voltage creates a time-varying electric field between the fingers. The direction of the electric field is lateral (i.e., laterally excited), or primarily parallel to the surface of the piezoelectric layer 410, as indicated by the arrows labeled “electric field.” Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is Defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for ease of visualization in FIG. 4. While the atomic motions are predominantly lateral (i.e., horizontal as shown in FIG. 4), the direction of acoustic energy flow of the primarily excited shear acoustic mode is substantially and/or primarily orthogonal to the surface of the piezoelectric layer, as indicated by the arrow 465.

A bulk acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

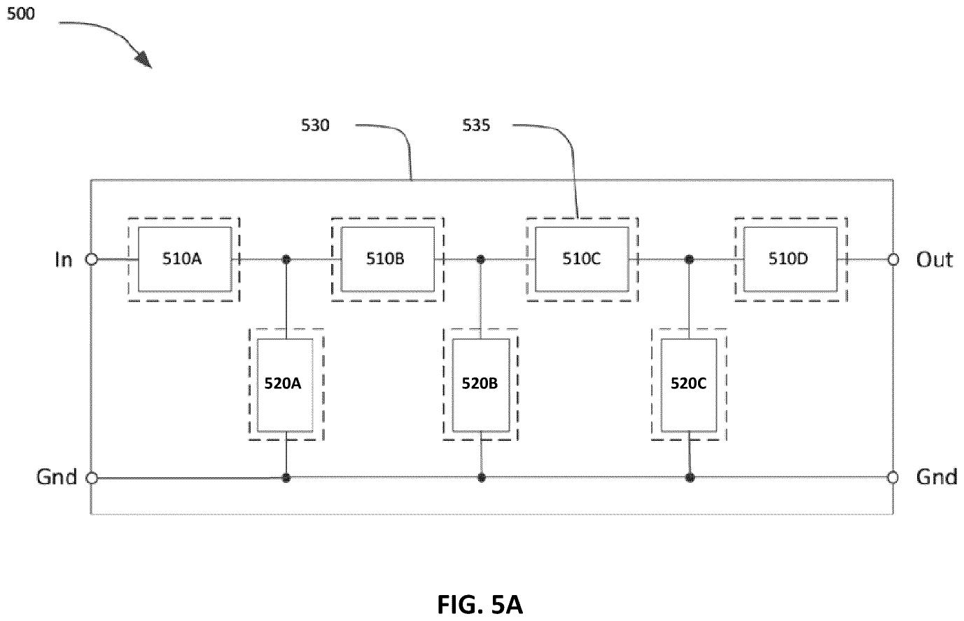

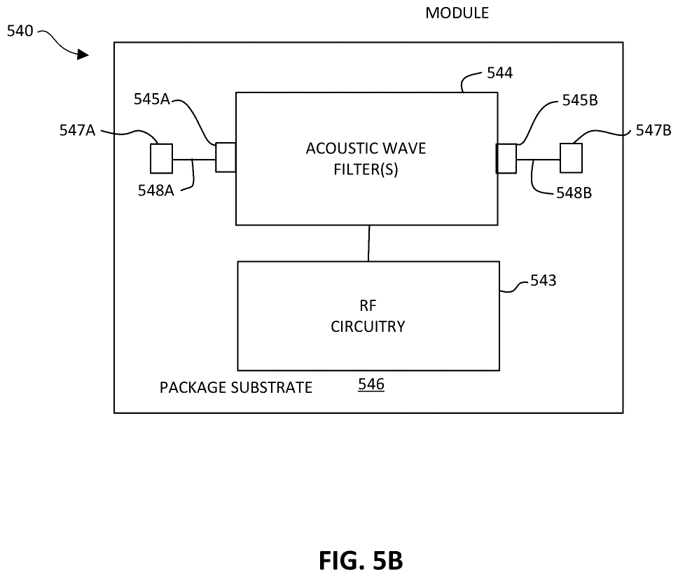

FIG. 5A is a schematic circuit diagram and layout for a high frequency bandpass filter 500 using XBARs, such as the general XBAR configuration 100 (e.g., the bulk acoustic resonators) described above, for example. The filter 500 has a conventional ladder filter architecture, which may include a split-ladder filter architecture wherein the filter is split between multiple chips, that has a plurality of bulk acoustic resonators including four resonators 510A, 510B, 510C, and 510D and three shunt resonators 520A, 520B and 520C. The series resonators 510A, 510B, 510C and 510D are connected in series between a first port and a second port (hence the term “series resonator”). In FIG. 5A, the first and second ports are labeled “In” and “Out”, respectively. However, the filter 500 is bidirectional and either port may serve as the input or output of the filter. At least two shunt resonators, such as the shunt resonators 520A and 520B, are connected from nodes between series resonators to a ground connection. A filter may contain additional reactive components, such as inductors, not shown in FIG. 5A. All the shunt resonators and series resonators are XBARs (e.g., either of the XBAR configurations 100 and/or 100′ as discussed above) in the exemplary aspect. The inclusion of three series and two shunt resonators is an example. A filter may have more or fewer than five total resonators, more or fewer than three series resonators, and more or fewer than two shunt resonators. Typically, for a split ladder and non-split-ladder filter architectures, all of the series resonators are connected in series between an input and an output of the filter, and all of the shunt resonators are typically connected between ground and the input, the output, or a node between two series resonators.

In the exemplary filter 500, the series resonators 510A, 510B, 510C and 510D and the shunt resonators 520A, 520B and 520C of the filter 500 are formed on at least one, and in some cases a single, piezoelectric layer 530 of piezoelectric material bonded to a silicon substrate (not visible). However, in alternative aspects, the individual resonators may each be formed on a separate respective piezoelectric layer for each resonator wherein all resonators are located on the same chip. In some cases, however different resonators of a filter may be bonded to a separate substrate, for example. This may result in a split-ladder architecture that can include one or a plurality of separate chips that include separate piezoelectric layers and IDTs of one or more bulk acoustic resonators that are then configured together to form the overall split ladder filter. Moreover, each resonator includes a respective IDT (not shown), with at least the fingers of the IDT disposed over a cavity, or an acoustic mirror, in the substrate. In this and similar contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance (also interchangeably referred to as Y-parameter) of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500.

According to an exemplary aspect, each of the series resonators 510A, 510B, and 510C and the shunt resonators 520A and 520B can have an XBAR configuration as described above with respect to FIGS. 1A-2D in which a diaphragm with IDT fingers spans over a cavity. Alternatively, each of the series resonators 510A, 510B, 510C, 510D and the shunt resonators 520A, 520B, and 520C can have an XBAR configuration in which the series resonators 510A, 510B, 510C, 510D and/or the shunt resonators 520A, 520B, and 520C can be solidly mounted on or above a Bragg mirror (e.g., as shown in FIG. 2E), which in turn can be mounted on a substrate.

FIG. 5B is a schematic diagram of a radio frequency module that includes an acoustic wave filter device according to an exemplary aspect. In particular, FIG. 5B illustrate a radio frequency module 540 that includes one or more acoustic wave filters 544 according to an exemplary aspect. The illustrated radio frequency module 540 also includes radio frequency (RF) circuitry (or RF circuit) 543. In an exemplary aspect, the acoustic wave filters 544 may include one or more of filter 500 including XBARs (e.g., the bulk acoustic resonators described herein), as described above with respect to FIG. 5A.

The acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures to, for example, provide protection and/or facilitate easier handling of the radio frequency module 540. Such a packaging structure can include an overmold structure formed over the package substrate 546. The overmold structure can encapsulate some or all of the components of the radio frequency module 540.

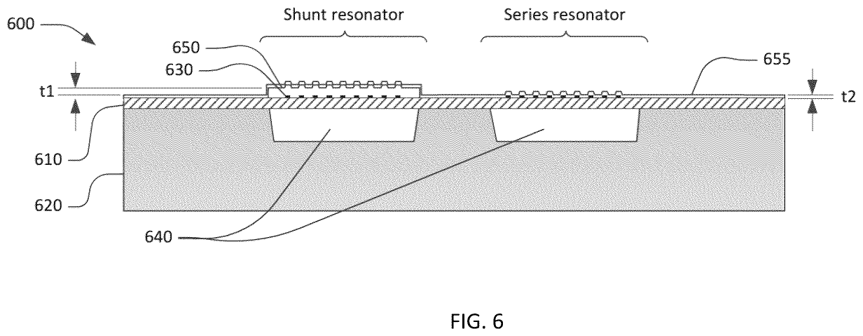

FIG. 6 is a schematic cross-sectional view through a shunt resonator and a series resonator of a filter 600 that uses a dielectric frequency setting layer to separate and/or distinguish the resonance frequencies of shunt and series resonators. A piezoelectric layer 610 is attached to a substrate 620. Portions of the piezoelectric layer 610 form diaphragms spanning cavities 640 in the substrate 620. In an exemplary aspect, a single piezoelectric layer 610 is shown in FIG. 6, which spans multiple cavities 640. In another exemplary aspect, a plurality of separate piezoelectric layers can each span a respective cavity 640.

In either event, interleaved IDT fingers, such as finger 630, are formed on the diaphragms. The interleaved IDT fingers 630 can correspond to fingers 136, 238a, 238b, for example. Moreover, a first dielectric layer 650, having a thickness t1, is formed over the IDT of the shunt resonator. In an exemplary aspect, the first dielectric layer 650 can be provided as considered a “frequency setting dielectric layer,” which is a layer of dielectric material applied to a first subset of the resonators in a filter to offset the resonance frequencies of the first subset of resonators with respect to the resonance frequencies of resonators that do not receive the frequency setting dielectric layer. In an exemplary aspect, the frequency setting dielectric layer may be formed using SiO₂. The frequency setting dielectric layer may also be formed using silicon dioxide, silicon nitride, aluminum oxide, aluminum nitride, beryllium oxide, tantalum oxide, tungsten oxide, or some other dielectric material. The frequency setting dielectric layer may be formed using a laminate or composite of two or more dielectric materials.

A second dielectric layer 655, having a thickness t2, may be deposited over both the shunt and series resonators. According to an exemplary aspect, the second dielectric layer 655 can be provided to seal and passivate the surface of the filter 600. The second dielectric layer may be formed using the same material as the first dielectric layer or a different material. The second dielectric layer may be formed using a laminate or composite of two or more different dielectric materials. Further, as will be described subsequently, the thickness of the second dielectric layer may be locally adjusted to fine-tune the frequency of the filter 600. Thus, the second dielectric layer can be referred to as the “passivation and tuning layer.”

The resonance frequency of an XBAR may be approximately proportional to the inverse of the total thickness of the diaphragm including the piezoelectric layer 610 and the dielectric layers 650, 655. That is, thinner XBARs may have higher resonant frequencies than thicker XBARs that otherwise have the same configuration. The diaphragm of the shunt resonator may be thicker than the diaphragm of the series resonator by the thickness t1 of the dielectric frequency setting layer 650. Thus, the shunt resonator will have a lower resonance frequency than the series resonator. The difference in resonance frequency between series and shunt resonators may be determined by the thickness t1.

As previously described, the primary acoustic mode in an XBAR is a shear mode. Other modes (e.g., spurious modes) may also be excited. To avoid unacceptable distortions in the performance of a filter, such spurious modes may be controlled by reducing the magnitude of the spurious mode to a negligible level, moving the spurious mode to a frequency where the spurious mode does not have a negative impact on filter performance, and/or the like.

Spurious modes in XBARs may originate from the lowest order antisymmetric Lamb wave (A0) and its specific interaction with the primary shear mode in the presence of the IDT fingers. The asymmetric structure of an existing (e.g., asymmetric) XBAR, with IDT fingers and dielectric layers on only one side of the piezoelectric diaphragm, facilitates excitation of spurious modes. Spurious modes can be controlled, to some extent, by proper selection of the IDT pitch and mark. This method (e.g., the proper selection of the IDT pitch and mark) provides control over some selected spurs near a passband but not the out of band spurs, whose presence affects the ability to satisfy stop-band rejection specifications.

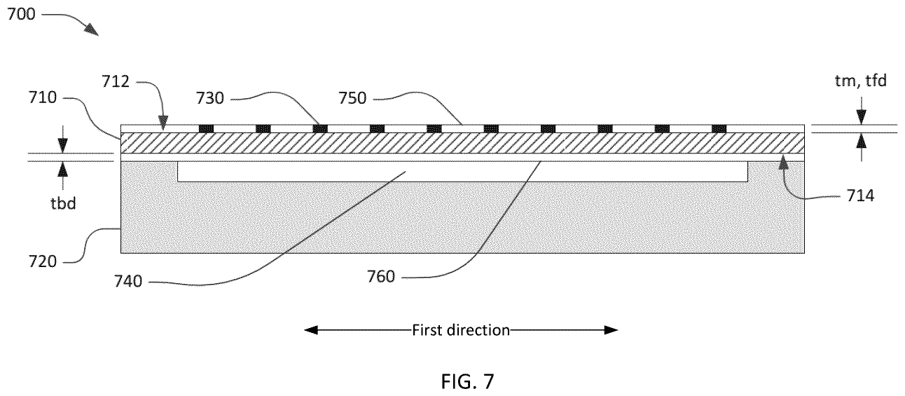

However, a symmetric structure, such as a symmetrical XBAR (SXBAR) structure, may reduce (e.g., significantly reduce) spurs over a wide frequency band. An SXBAR structure may include IDT fingers and a dielectric layer on one side (e.g., a front side) of the piezoelectric layer and at least another dielectric layer on another side (e.g., a back side) of the piezoelectric layer, such as shown in FIG. 7.

In an aspect, an SXBAR structure (e.g., the most symmetric structure) may replicate IDT fingers and dielectric layers on both sides of the piezoelectric diaphragm. An SXBAR structure (e.g., an almost symmetric structure) may add dielectric fingers with similar acoustic properties to the conductive IDT fingers to the back surface of the diaphragm. In either of the approaches, the fingers on the back side of the diaphragm may be formed (e.g., deposited and patterned) prior to bonding the piezoelectric diaphragm to the supporting substrate. In some examples, this may greatly complicate the XBAR fabrication process.

FIG. 7 is a schematic cross-sectional view of an effectively symmetric XBAR 700. The XBAR 700 includes a piezoelectric layer 710 supported by a substrate 720. The piezoelectric layer 710 may be 120Y-cut, Z-cut, rotated Z-cut, or rotated YX-cut lithium niobate or lithium tantalate, or the like. The substrate 720 may be formed using silicon or some other material that allows the formation of cavities (e.g., deep cavities) by, for example, isotropic etching. A portion of the piezoelectric layer 710 forms a diaphragm spanning a cavity 740 in the substrate 720.

IDT fingers, such as finger 730, are formed on a front surface 712 of the diaphragm portion (i.e., the portion spanning the cavity 740) of the piezoelectric layer 710. The IDT fingers have a thickness tm. A front-side dielectric layer 750 is formed on the front surface 712 of the piezoelectric layer 710 between the IDT fingers. The example shown in FIG. 7 does not include the front-side dielectric layer 750 on the IDT fingers. The example shown in FIG. 7 includes only the front-side dielectric layer 750 between the fingers. However, other aspects of the symmetrical XBAR configuration of FIG. 7 may include a front-side dielectric layer that has a larger thickness than the IDT fingers and therefore covers the IDT fingers. The front-side dielectric layer 750 has a thickness tfd. In the example shown in FIG. 7, tm is equal to tfd. In another example, tm is larger than tfd. A back-side dielectric layer 760 is formed on a back surface 714 of the piezoelectric layer 710. The back-side dielectric layer 760 has a thickness tbd.

In some examples, the XBAR structure shown in FIG. 7 has two potential benefits over the XBAR structure shown in the previous figures. First, the presence of the front-side dielectric layer 750 between the IDT fingers 730 reduces reflections from the IDT fingers for laterally propagating (i.e., propagating in the left-right direction in FIG. 7) spurious modes. Reducing these reflections may reduce or minimize constructive interference of the laterally propagating modes and thus reduces their magnitudes.

Acoustic impedance Z may be defined as the product of density and propagation velocity of a material. Since the primary acoustic mode of an XBAR is a shear mode, in this disclosure the term “acoustic impedance” is specifically defined as the product of density and shear mode propagation velocity. The unit of measurement for acoustic impedance is the “Rayl”. The reflections from the IDT fingers 730 may be determined, in part, by the acoustic impedance mismatch between the fingers and the environment of the fingers. In an example, when the thickness and acoustic impedance of the IDT fingers 730 and the front-side dielectric layer 750 are equal, reflections from the IDT fingers for these modes may be significantly reduced or minimized. Although a precise impedance match between the IDT fingers and the front-side dielectric layer may not be achieved in some examples, several combinations of metal and dielectric materials have sufficiently similar acoustic properties to substantially reduce reflection from the IDT fingers. For example, the combination of aluminum (Z=8.45 MRayl) and silicon dioxide (Z=8.3 MRayl) or the combination of copper (Z=20.25 MRayl) and tantalum oxide (Ta₂O₅, Z=22.6 MRayl) may be used for the IDT fingers 730 and front-side dielectric layer 750, respectively. Other metal/dielectric combinations may be used. In some aspects, the metal and dielectric combinations may satisfy the relationship 0.8 Zm≤Zfd≤1.25 Zm to substantially reduce reflection from the IDT fingers, where Zm is the acoustic impedance of the metal IDT fingers 730 and Zfd is the acoustic impedance of the front-side dielectric layer 750.

A second benefit of the XBAR structure shown in FIG. 7 is the presence of dielectric layers 750 and 760 on both sides of the diaphragm, which may reduce coupling to certain spurious modes. In this disclosure, the term “acoustic thickness” is defined as the thickness of a structure measured in wavelengths of the primary shear acoustic wave in the material of the structure. The term “thickness” means the physical or mechanical thickness. According to an exemplary aspect, the XBAR 700 may be structured such that an acoustic thickness of the back-side dielectric layer 760 is in a range defined by 0.5×tfd_acoustic and 1.5×tfd_acoustic where tfd_acoustic is the acoustic thickness of the front-side dielectric layer 750. In an aspect, the XBAR 700 may be structured such that the acoustic thickness of the front-side dielectric layer 750 and the acoustic thickness of the back-side dielectric layer 760 are substantially equal. “Substantially equal” means “as equal as practical within normal manufacturing tolerances.” In the case that the front-side dielectric layer 750 and the back-side dielectric layer 760 are made of the same material, equal acoustic thickness of the two layers is correlated to the same (physical) thickness.

Substantial equality of the XBAR 700 may be preferred but not necessary to achieve a significant reduction in spurious modes. Some spurious modes may be reduced if the acoustic thickness of the back-side dielectric layer 760 is at least one-third and less than two-thirds of the total acoustic thickness of the back-side and front-side dielectric layers 760 and 750. When the front-side and back-side dielectric layers are the same material, significant reduction of at least some spurious modes may be achieved when 0.5 tfd≤tbd≤1.5 tfd.

In some examples, acoustic energy that leaks from the resonator in the transverse direction (i.e., the direction parallel to the IDT fingers) may increase with the length of the resonator and thus may increase with the number of IDT fingers. In contrast, energy lost from the ends of the IDT in the longitudinal direction (i.e. the direction normal to the IDT fingers such as a first direction or a longitudinal direction in FIG. 7) may be independent from the number of IDT fingers. In some examples, as the number of IDT fingers and the peak energy stored in an XBAR is reduced, the acoustic energy lost in the longitudinal direction may become an ever-increasing fraction of the peak energy stored.

According to an exemplary aspect, the “SXBAR” is shown in FIG. 7 and provides performance benefits related to reducing spurious modes based on the front-side and back-side dielectric layers. However, in some examples, an XBAR having a symmetrical configuration such as the SXBAR structure is associated with certain performance challenges along with benefits.

For example, SXBAR resonator devices show increased longitudinal energy leakage (e.g., energy leakages along the first direction or the longitudinal direction in FIG. 7) as compared to standard XBAR devices (e.g., XBAR devices that are not symmetric).

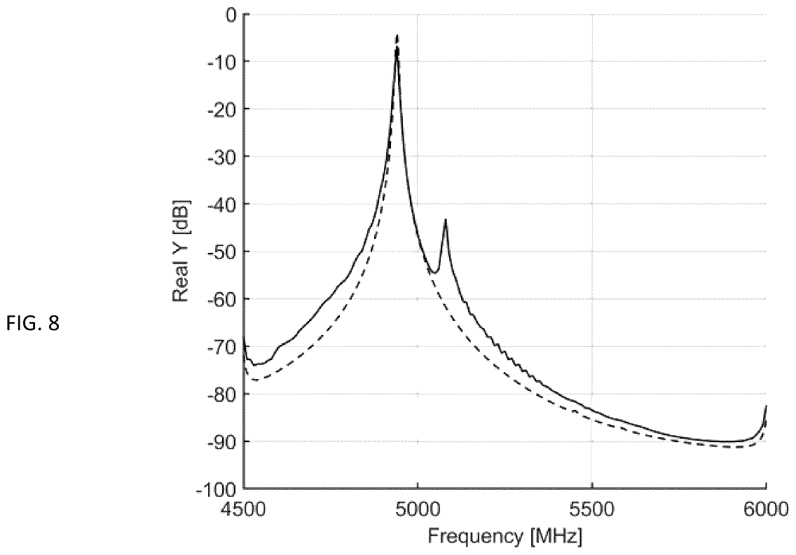

FIG. 8 shows a comparison between two simulated performances of an SXBAR resonator including ideal performance (dashed line) of the SXBAR resonator, such as the one described above with respect to FIG. 7, and actual performance (solid line) of the SXBAR resonator. The dashed line in FIG. 8 shows the ideal performance of the SXBAR resonator, free of two-dimensional (2D) energy leakage, and may be obtained, for example, using a 2Dp simulation.

The solid line in FIG. 8 shows actual simulated performance of an SXBAR resonator without any grating structure to control energy leakage and may be obtained, for example, using a 2Df simulation. As shown in FIG. 8, the actual simulated performance indicates a significant spur above the resonance frequency, with significant additional loss extending to the higher frequencies.

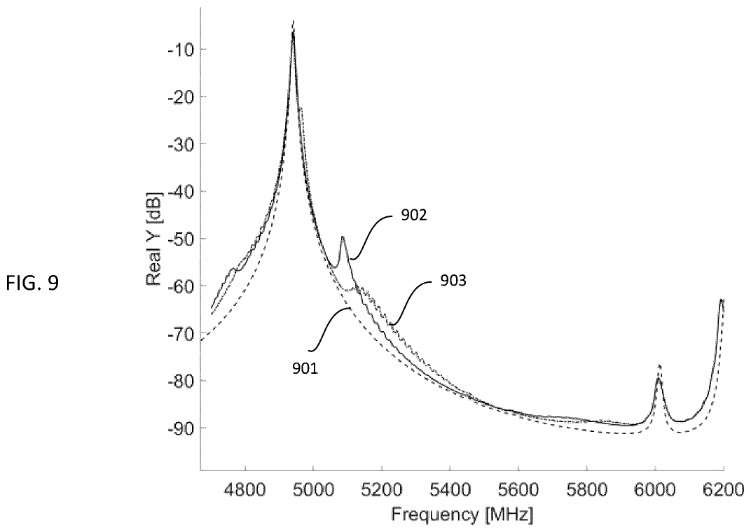

Accordingly, as shown in FIG. 8, the significant energy leakage of an SXBAR resonator may, for example, necessitate a grating structure to control the energy loss. However, related grating structures used in standard XBAR devices may not be sufficiently effective in reducing the longitudinal energy leakage of the SXBAR devices, such as shown in FIG. 9. FIG. 9 shows simulated performance of XBAR structures with and without related gratings typically used in standard XBAR structures.

The related gratings typically used in standard XBAR structures may include two grating fingers, for example, on each side of the IDT with a pitch having a value in a range from 1×pIDT to 1.5×pIDT, where pIDT is the pitch of the IDT fingers of the XBAR. The mark of the grating fingers in the related gratings typically used in standard XBAR structures is in a range from 0.7 μm to 1.3 μm.

In FIG. 9, the dashed line 901 represents the ideal XBAR performance, as in FIG. 8. A solid line 902 represents performance of the XBAR without a grating, as the solid line in FIG. 8. A solid line 903 represents performance of the XBAR with a typical grating structure having dimensions in the ranges described above. As shown in FIG. 9, such typical grating structures do not sufficiently recover the ideal performance of the dashed line 901, due to the visible spurs and significant energy loss across the frequency spread.

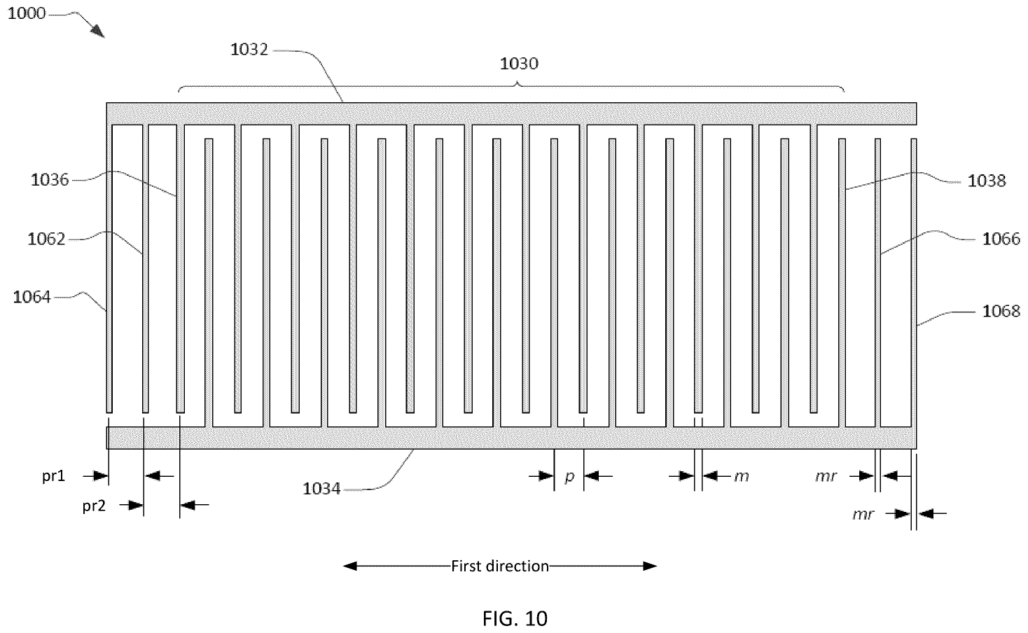

Accordingly, a new grating structure with, for example, different dimensions may be used to address the longitudinal energy leakage that occurs in SXBAR devices. FIG. 10 is directed to a first aspect of the new grating structure for an XBAR configuration. FIG. 10 shows a top view of an example conductor pattern 1000 that reduces the acoustic energy leakage in the longitudinal direction at the ends of an SXBAR.

The conductor pattern 1000 includes an IDT 1030 and grating elements including four fingers (also referred to as reflector fingers or grating fingers) 1062, 1064, 1066, and 1068, two on each side of the IDT 1030. The terms “reflector finger” and “grating finger” are used interchangeably herein, as are the terms “reflector element” and “grating element.” The reflector fingers 1062 and 1064 on one end of the IDT 1030 may be considered one reflector element (or one grating element or a first grating element) and the reflector fingers 1066 and 1068 on the other end of the IDT 1030 may be considered another reflector element or grating element, such as a second grating element. Thus, the first grating element and the second grating element are opposing sides in the lengthwise direction of the IDT 1030.

The IDT 1030 includes a first busbar 1032, a second busbar 1034, and a plurality of interleaved IDT fingers extending alternately from the first and second busbars. In this example, n, the number of IDT fingers, is equal to 24. In other SXBARs, n may be in a range from 20 to 100 or more IDT fingers, for example. IDT finger 1036 is the 1st IDT finger and IDT finger 1038 is the n'th IDT finger. In other words, the IDT fingers include a first (or 1st) IDT finger and an nth (or n'th or last) IDT finger that are at opposing ends of the IDT 1030 in the lengthwise direction thereof. Numbering the IDT fingers from left to right (as shown in FIG. 10) is arbitrary and the designations of the 1st and nth IDT fingers can be reversed as should be appreciated to one skilled in the art.

As shown in FIG. 10, the odd numbered IDT fingers extend from the first busbar 1032 and the even numbered IDT fingers extend from the second busbar 1034. The IDT 1030 has an even number of IDT fingers such that the 1st and n'th IDT fingers 1036 and 1038 extend from different busbars. In some cases, an IDT may have an odd number of IDT fingers such that the 1st and n'th IDT fingers and all of the reflector elements extend from the same busbar.

According to an aspect, a total of four reflector fingers are provided outside of periphery of the IDT 1030. A first reflector finger 1062 is adjacent and parallel to 1st IDT finger 1036 at the left end of the IDT 1030. A second reflector finger 1066 is adjacent and parallel to n'th IDT finger 1038 at the right end of the IDT 1030. Thus, the second finger 1066 of the two fingers of the first grating element is located on an opposite side of the first finger 1062 of the two fingers of the first grating element with respect to the first IDT finger 1036.

A third reflector finger 1064 is parallel to the first reflector finger 1062. A fourth reflector finger 1068 is parallel to the second reflector finger 1066. Thus, the fourth finger 1068 of the two fingers of the second grating element is located on an opposite side of the third finger 1064 of the two fingers of the second grating element with respect to the IDT finger 1038. It is also noted that while the aspect shown in FIG. 10 includes two reflector fingers on either end of the IDT 1030, the number of reflector fingers may be modified to one or to more than two.

In the example shown in FIG. 10, first and third reflector fingers 1062, 1064 extend from the first busbar 1032 (e.g., a same one of the busbars) and thus are at the same electrical potential as the 1st IDT finger 1036. Similarly, second and fourth reflector fingers 1066 and 1068 extend from the second busbar 1034 (e.g., a same one of the busbars) and thus are at the same electrical potential as the n'th IDT finger 1038.

The reflector fingers 1062, 1064, 1066, 1068 are configured to confine acoustic energy to the area of the IDT 1030 and thus reduce acoustic energy losses in a first direction (also referred to as the longitudinal direction) shown in FIG. 10. A pitch pr1 between adjacent reflector fingers and a pitch pr2 between reflector fingers 1062 and 1066 and the adjacent first and n'th IDT fingers, respectively, may be set to optimize performance within the required frequency range. pr1 and pr2 may be equal or different. A width or a mark mr (e.g., a grating mark mr) of the reflector fingers 1062, 1064, 1066, 1068 is not necessarily equal to the mark m of the IDT fingers, and may also be set to optimize performance at frequencies of interest.

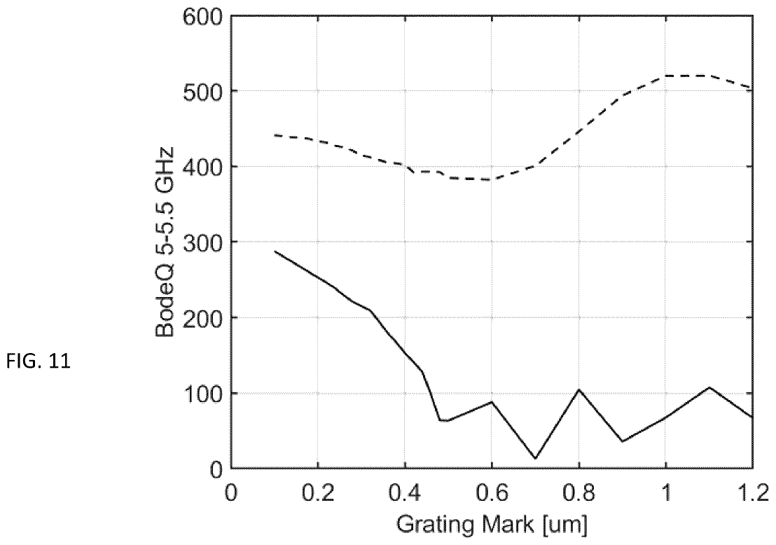

FIG. 11 shows a graph of SXBAR performance when operating in a frequency range of 5 to 5.5 GHz. The solid line shows a minimum BodeQ across different mark dimensions of the grating fingers, while the dashed line shows a median BodeQ across the mark dimensions of the grating fingers. A BodeQ refers to a Q factor calculated from a Bode plot. The minimum BodeQ and the median BodeQ may be obtained from BodeQs in the frequency range of 5 to 5.5 GHz. For the measurements of FIG. 11, two reflector fingers are used per side, as shown in FIG. 10, and the pitch pr1 of the reflector fingers is set at 1.3×pIDT. In an example, pr2 is equal to pr1.

As shown in FIG. 11, a grating mark mr of 1 μm, which is used in typical XBAR devices, has good median BodeQ performance. However, this grating mark mr (1 μm) has low minimum BodeQ. On the other hand, both minimum BodeQ and median BodeQ have favorable values at very small mark measurements (e.g., grating mark mr being approximately 0.2 μm and less), according to FIG. 11.

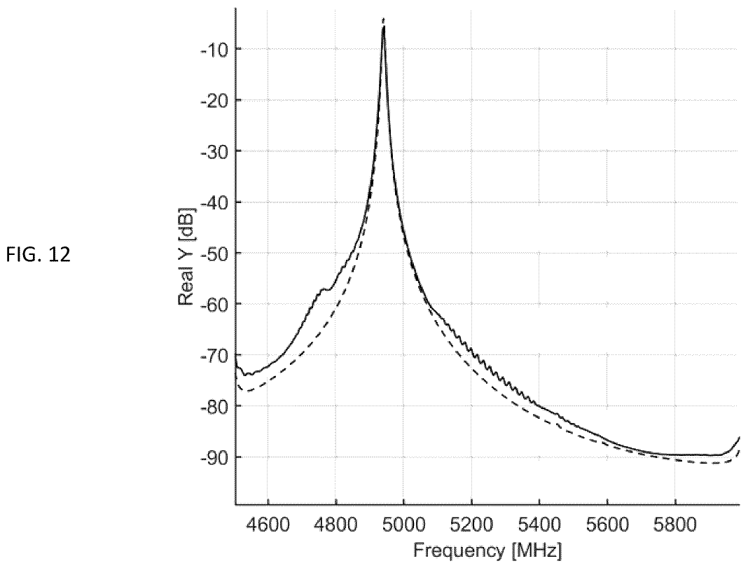

To corroborate the result garnered from FIG. 11 that relatively small mark dimensions of grating fingers may provide the best level of performance improvement in SXBAR devices, FIG. 12 plots a simulation of the performance of an SXBAR including grating fingers having a mark (mr) of 0.1 μm. The performance of the SXBAR including grating fingers having a mark of 0.1 μm is shown as a solid line in FIG. 12, in comparison with the ideal performance (shown in a dashed line) previously included in FIGS. 8 and 9.

As can be seen in the simulation in FIG. 12, the performance of the SXBAR including grating fingers having a mark of 0.1 μm significantly reduces or eliminates spurs and generally shows lower energy loss than (i) previously described grating structures having wider mark dimensions and (ii) some XBAR or SXBAR structures without a grating structure. As shown in the simulation of FIG. 11, performance continues to improve with a decrease of the grating mark mr dimension to values as small as 0.5 μm. In an aspect, the grating mark of at least one of the grating fingers 1062, 1064, 1066, and 1068 is less than or equal to 0.5 μm. Accordingly, the mark of the grating fingers may be made as small as possible to achieve the most performance gain, although the lower limit of possible grating mark dimensions may be set by manufacturing limitations.

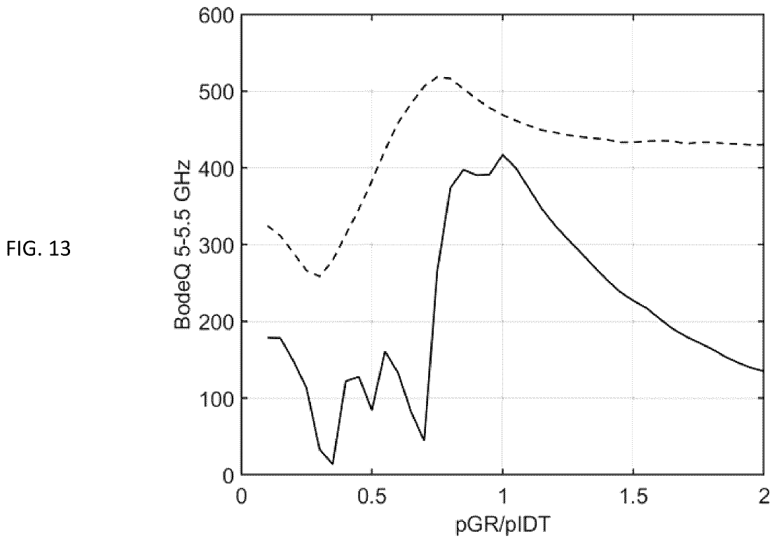

It is also appreciated that the pitch dimension of the grating fingers may affect performance of the SXBAR in the operating range of 5-5.5 GHz. FIG. 13 plots a simulation of a performance of an SXBAR in the operating range of 5-5.5 GHz against a ratio of the pitch (e.g., pr1) of the grating fingers to the pitch of the IDT fingers. That is, a value of 1 for the dimension pGR/pIDT indicates that the pitch of the grating fingers is the same as the pitch of the IDT fingers.

As shown in FIG. 13, the solid line shows a minimum BodeQ versus the ratio pGR/pIDT, while the dashed line shows a median BodeQ versus the ratio pGR/pIDT. A positive performance of the SXBAR is tied to ratio values in the range of 0.8 to 1.5. Accordingly, the pitch of the grating fingers may be set within the range of 80% to 150% of the pitch of the IDT fingers to achieve reduction of the energy leakage of SXBAR devices.

As described above in FIGS. 10-13, in an aspect, an SXBAR device may include an IDT (e.g., 1030) including IDT fingers (e.g., 1036) on a front surface of a piezoelectric layer, a front-side dielectric layer over the IDT fingers, a back-side dielectric layer on a back surface of the piezoelectric layer, and a grating structure such as described in FIG. 10. In an example, the front-side dielectric layer completely covers the IDT fingers, and a thickness tfd of the front-side dielectric layer completely is larger than or equal to tm of the IDT fingers. For example, the IDT fingers may be formed on the front surface of the piezoelectric layer, dielectric material(s) may be formed over the IDT fingers, and a planarization process may be performed. In an example, the grating structure includes two grating fingers at each side of the IDT. In an example, a grating mark of the first grating finger 1062 is less than 0.5 μm to achieve a certain BodeQ, such as described in FIG. 11. In an example, an acoustic thickness of the back-side dielectric layer is in a range defined by 0.5×tfd_acoustic and 1.5×tfd_acoustic where tfd_acoustic is the acoustic thickness of the front-side dielectric layer. In an example, a pitch (e.g., pr1) between the two adjacent grating fingers (e.g., 1062 and 1064) is in a range defined by 0.8×pIDT and 1.5×pIDT.

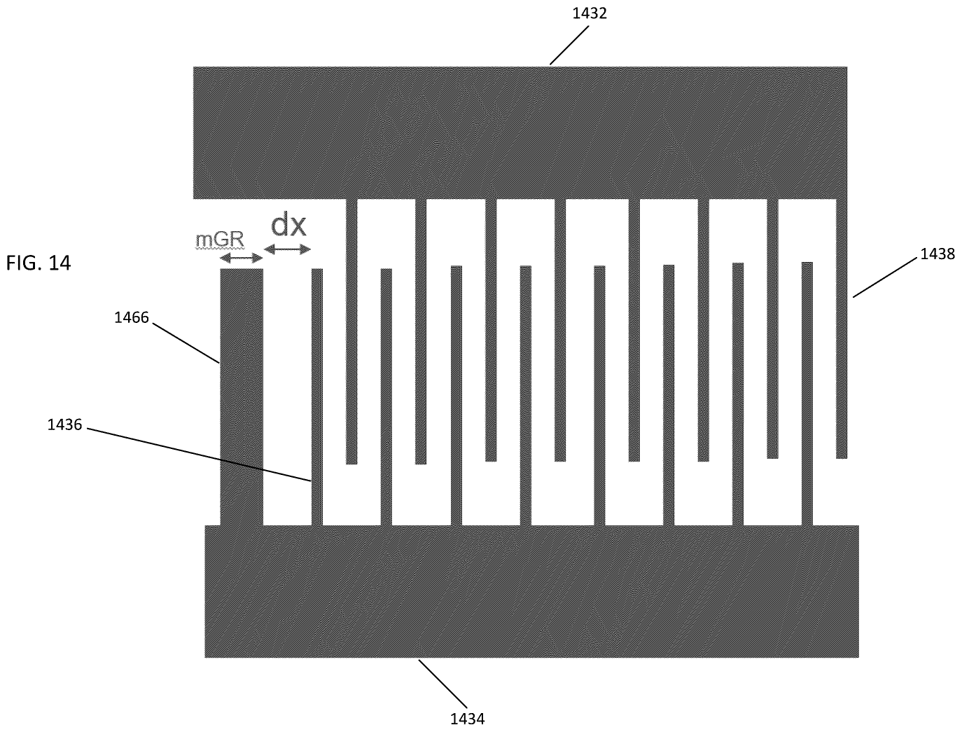

FIG. 14 shows another aspect of a grating structure configured to decrease the longitudinal energy leakage of SXBAR devices. In should generally be understand that the IDT fingers including a first IDT finger 1436 and a last IDT finger (the n'th IDT finger) 1438 shown in FIG. 14 disposed on a piezoelectric diaphragm and over a cavity, for example. As shown in this aspect, only a single bar (also referred to as a grating bar) 1466 extending from busbar 1434 and having a width or a mark mGR is placed a distance dx away from the first IDT finger 1436. In an aspect, the mark mGR of the grating bar 1466 is not the same as the mark of the IDT fingers and the distance dx is not the same as the pitch of the IDT fingers. Having only a single grating bar 1466 may simplify the design and manufacturing process of SXBAR devices as well as reduce cost, for example.

The grating bar 1466 may be attached to the same busbar 1434 as the first IDT finger 1436 that is closest to the grating bar 1466. In other aspects, another grating bar (not shown) may be located a distance dx from the n'th IDT finger 1438. In an example, the other grating bar may be attached to the same busbar (the busbar 1432 in the example of FIG. 14) as the n'th IDT finger 1438.

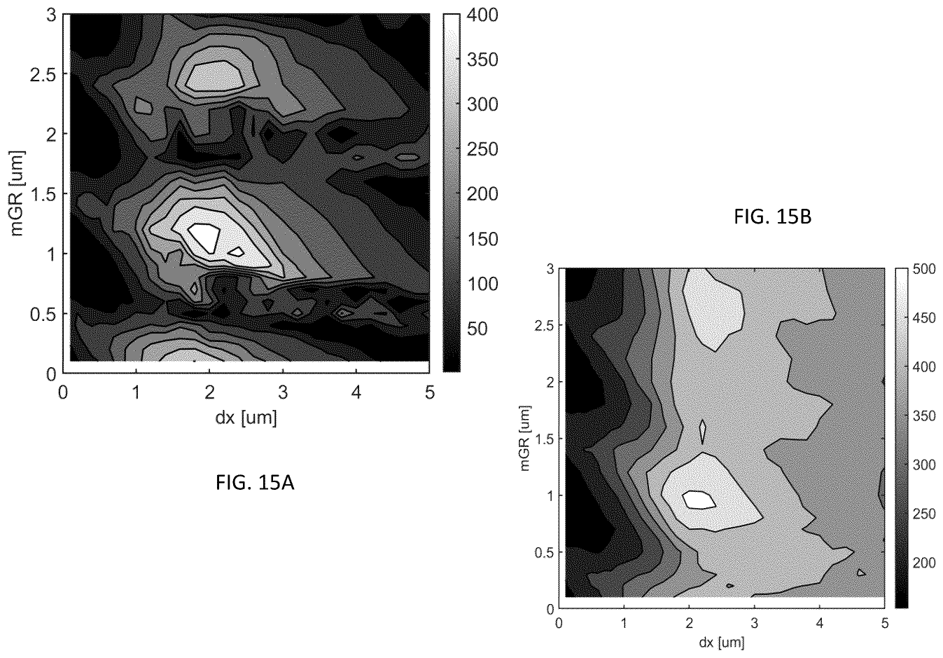

To determine optimal dimensions for mGR and dx, minimum BodeQ and mean BodeQ measurements are made in the operating frequency range of 5-5.5 GHZ, as shown in FIGS. 15A and 15B, respectively. In FIG. 15A, a heat map style plot shows a minimum BodeQ at various combinations of values for dx and mGR.

Maxima are indicated by the lighter shaded areas in FIG. 15A, one of which is associated with a value of around 1.2 μm for the mark (i.e., width) mGR of the grating bar and a value around 2 μm for the distance dx between the grating bar 1466 and the closest IDT finger (e.g., 1436). Another local maximum appears around a value of 2.5 μm for the mark mGR with the distance dx still at approximately 2 μm. It is reiterated that the width of the IDT and grating fingers/bars is measured in a lengthwise direction of the IDT that is perpendicular to a direction in which the IDT fingers extend and is also parallel to a surface of the substrate.

The mean BodeQ heat map style plot of FIG. 15B shows maxima similar to those in the minimum BodeQ of FIG. 15A, without indicating potential spurs in the optimal regions. Accordingly, taken together, FIGS. 15A and 15B indicate optimal mark and distance values for the grating bar 1466 to improve SXBAR device performance by reducing energy leakage. The patterns shown in FIGS. 15A-15B are nontrivial with multiple optima.

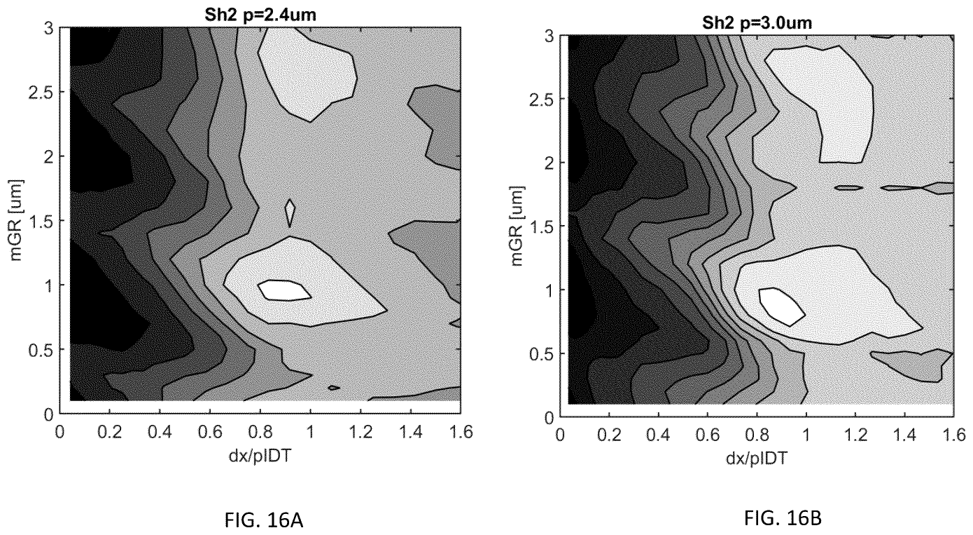

FIGS. 16A and 16B further explore the relationship between the distance dx between the grating bar 1466 and the closest IDT finger and the pitch (pIDT) of the IDT fingers. FIG. 16A is a heat map style plot showing performance of a device having a pIDT of 2.4 μm, while FIG. 16B is a heat map style plot showing performance of a device having a pIDT of 3 μm.

As can be seen, the maxima in both FIGS. 16A and 16B are consistent, showing a relationship between SXBAR performance and the ratio of dx to pIDT. In both graphs, a maximum performance appears around a value of 0.9 for the ratio of dx (the distance between the grating bar 1466 to the closest IDT finger) to pIDT (the pitch of the IDT fingers).

Dimensions of the grating bar aspect shown in FIG. 14 may be optimized based on the above-described metrics to select an appropriate mark mGR and an appropriate distance dx from the closest IDT finger. In an example, the distance dx is larger than or equal to 0.8×pIDT and is less than 1.0×pIDT. That is, the distance dx is in a range between 0.8×pIDT and 1.0×pIDT. In an example, the preferable distance dx is approximately 0.9×pIDT.

In an exemplary aspect, the optimum width mGR may be around 0.9 μm, for example in the range of 0.8 μm to 1.2 μm. Because the dimensions are optimized in the operational range of 5 to 5.5 GHZ, an SXBAR having a grating bar structure with the above-described optimized dimensions may be suitable for use in Wi-Fi devices.

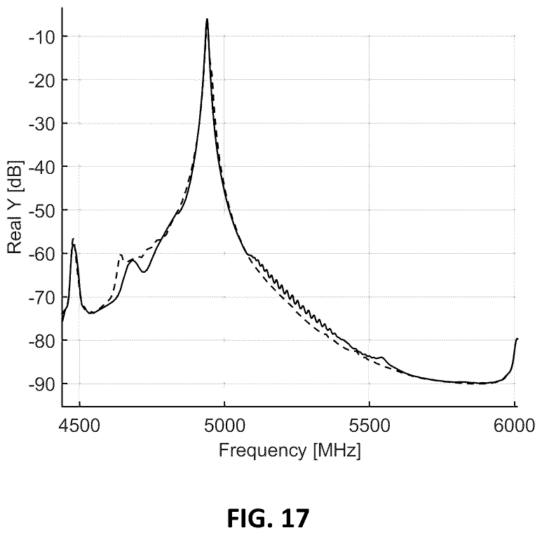

FIG. 17 compares simulated performance of two SXBARs including the grating fingers shown in FIG. 10 and the grating bar in FIG. 14, respectively. The performance of the SXBAR including the grating fingers shown in FIG. 10 is indicated by a solid line. The performance of the SXBAR including the grating bar shown in FIG. 14 is indicated by a dashed line. As can be seen in the simulation in FIG. 17, the performance of the SXBAR including the grating fingers and the grating bar significantly reduces spurs and shows relatively insignificant energy loss. FIG. 17 indicates that the grating fingers shown in FIG. 10 and the grating bar in FIG. 14 may introduce, for example, some energy loss at frequencies below the resonance frequency. For example, FIG. 17 shows increased loss for the SXBAR including the grating bar (indicated by the dashed line) especially in a 4.6 GHz to 4.7 GHz region, and in particular, the spur around 4.7 GHz seems to have become more pronounced. Accordingly, while the SXBAR including the grating bar or the grating fingers may be applied to shunt resonators and series resonators, in some examples, use of the grating fingers shown in FIG. 10 and the grating bar in FIG. 14 may be more suitable for shunt resonators than for series resonators because the extra loss is in a region (e.g., a low frequency region) that is outside the passband. Performance requirements outside the passband are much looser than performance requirements in and around the passband.

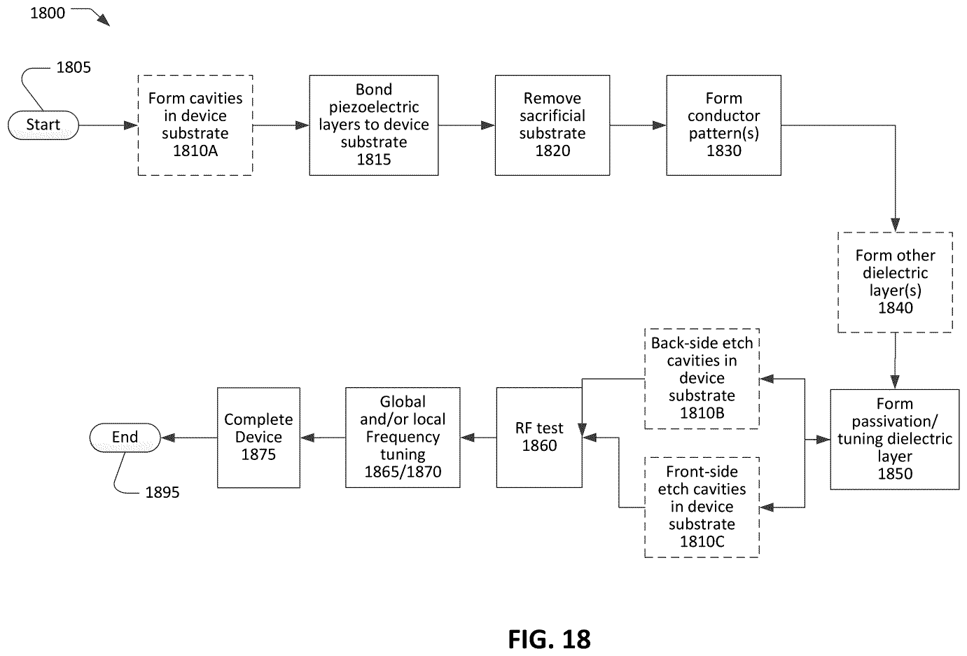

FIG. 18 is a simplified flow chart summarizing a process 1800 for fabricating a filter device incorporating XBARs such as SXBARs with and/or without a grating structure (e.g., the grating structure described in FIG. 10 or FIG. 14). Specifically, the process 1800 is for fabricating a filter device including multiple XBARs, some of which may include a frequency setting dielectric layer. In an example, the multiple XBARs include a plurality of SXBARs. One or more of the plurality of SXBARs may include the grating structure described in FIG. 10 or FIG. 14. The process 1800 starts at 1805 with a device substrate and a thin layer of piezoelectric material disposed on a sacrificial substrate. The process 1800 ends at 1895 with a completed filter device. The flow chart of FIG. 18 includes only major process steps. Various conventional process steps (e.g., surface preparation, cleaning, inspection, baking, annealing, monitoring, testing, etc.) may be performed before, between, after, and during the steps shown in FIG. 18.

While FIG. 18 generally describes a process for fabricating a single filter device, multiple filter devices may be fabricated simultaneously on a common wafer (consisting of a piezoelectric layer bonded to a substrate). In this case, each step of the process 1800 may be performed concurrently on all of the filter devices on the wafer.

The flow chart of FIG. 18 captures three variations of the process 1800 for making an XBAR which differ in when and how cavities are formed in the device substrate. The cavities may be formed at steps 1810A, 1810B, or 1810C. In an example, only one of these steps is performed in each of the three variations of the process 1800.

The piezoelectric layer may be, for example, lithium niobate or lithium tantalate, either of which may be Z-cut, rotated Z-cut, or rotated YX-cut. The piezoelectric layer may be some other material and/or some other cut. The device substrate may preferably be silicon. The device substrate may be some other material that allows formation of deep cavities by etching or other processing.

In one variation of the process 1800, one or more cavities are formed in the device substrate at 1810A, before the piezoelectric layer is bonded to the substrate at 1815. A separate cavity may be formed for each resonator in a filter device. The one or more cavities may be formed using conventional photolithographic and etching techniques. Typically, the cavities formed at 1810A does not penetrate through the device substrate.

At 1815, the piezoelectric layer is bonded to the device substrate. The piezoelectric layer and the device substrate may be bonded by a wafer bonding process. Typically, the mating surfaces of the device substrate and the piezoelectric layer are highly polished. One or more layers of intermediate materials, such as an oxide or metal, may be formed or deposited on the mating surface of one or both of the piezoelectric layer and the device substrate. One or both mating surfaces may be activated using, for example, a plasma process. The mating surfaces may then be pressed together with considerable force to establish molecular bonds between the piezoelectric layer and the device substrate or intermediate material layers.

At 1820, the sacrificial substrate may be removed. For example, the piezoelectric layer and the sacrificial substrate may be a wafer of piezoelectric material that has been ion implanted to create defects in the crystal structure along a plane that defines a boundary between what will become the piezoelectric layer and the sacrificial substrate. At 1820, the wafer may be split along the defect plane, for example by thermal shock, detaching the sacrificial substrate and leaving the piezoelectric layer bonded to the device substrate. The exposed surface of the piezoelectric layer may be polished or processed in some manner after the sacrificial substrate is detached.

Thin layers of single-crystal piezoelectric materials laminated to a non-piezoelectric substrate are commercially available. At the time of this application, both lithium niobate and lithium tantalate layers are available bonded to various substrates including silicon, quartz, and fused silica. Thin layers of other piezoelectric materials may be available now or in the future. The thickness of the piezoelectric layer may be between 300 nm and 1000 nm. When the substrate is silicon, a layer of SiO₂ may be disposed between the piezoelectric layer and the substrate. When a commercially available piezoelectric layer/device substrate laminate is used, steps 1810A, 1815, and 1820 of the process 1800 are not performed.

A first conductor pattern such as shown in FIG. 10 or FIG. 14, including IDTs and optionally reflector elements (e.g., (i) 1062, 1064, 1066, and/or 1068 in FIG. 10 or (ii) 1466 in FIG. 14) of each XBAR (e.g., an SXBAR), is formed at 1830 by depositing and patterning one or more conductor layers on the front side of the piezoelectric layer. The conductor layer may be, for example, aluminum, an aluminum alloy, copper, a copper alloy, or some other conductive metal. Optionally, one or more layers of other materials may be disposed below (i.e., between the conductor layer and the piezoelectric layer) and/or on top of the conductor layer. For example, a thin film of titanium, chrome, or other metal may be used to improve the adhesion between the conductor layer and the piezoelectric layer. A second conductor pattern of gold, aluminum, copper or other higher conductivity metal may be formed over portions of the first conductor pattern (for example the IDT bus bars and interconnections between the IDTs).

Each conductor pattern may be formed at 1830 by depositing the conductor layer and, optionally, one or more other metal layers in sequence over the surface of the piezoelectric layer. The excess metal may then be removed by etching through patterned photoresist. The conductor layer can be etched, for example, by plasma etching, reactive ion etching, wet chemical etching, or other etching techniques.

Alternatively, each conductor pattern may be formed at 1830 using a lift-off process. Photoresist may be deposited over the piezoelectric layer. and patterned to define the conductor pattern. The conductor layer and, optionally, one or more other layers may be deposited in sequence over the surface of the piezoelectric layer. The photoresist may then be removed, which removes the excess material, leaving the conductor pattern. In either case, the conductor pattern can be formed to include the grating structure as described herein such as shown in FIG. 10 or FIG. 14.

At 1840, one or more frequency setting dielectric layer(s) may be formed by depositing one or more layers of dielectric material on the front side of the piezoelectric layer. For example, a dielectric layer may be formed over the shunt resonators to lower the frequencies of the shunt resonators relative to the frequencies of the series resonators. The one or more dielectric layers may be deposited using a conventional deposition technique such as physical vapor deposition, atomic layer deposition, chemical vapor deposition, or some other method. One or more lithography processes (using photomasks) may be used to limit the deposition of the dielectric layers to selected areas of the piezoelectric layer. For example, a mask may be used to limit a dielectric layer to cover only the shunt resonators.

At 1850, a passivation/tuning dielectric layer is deposited over the piezoelectric layer and conductor patterns. The passivation/tuning dielectric layer may cover the entire surface of the filter except for pads for electrical connections to circuitry external to the filter. In some instantiations of the process 1800, the passivation/tuning dielectric layer may be formed after the cavities in the device substrate are etched at either 1810B or 1810C.

In an aspect, a front-side dielectric layer (e.g., 750 in FIG. 7) at a front surface of a piezoelectric layer of a resonator (e.g., a shunt resonator or a series resonator) may include the one or more frequency setting dielectric layer(s) such as described at 1840 and/or the passivation/tuning dielectric layer such as described at 1850. Referring to FIG. 6, when the resonator, such as the shunt resonator, includes the one or more frequency setting dielectric layer(s) (e.g., 650) and the passivation/tuning dielectric layer (e.g., 655), the front-side dielectric layer of the resonator can include the one or more frequency setting dielectric layer(s), such as described at 1840 (e.g., 650), and the passivation/tuning dielectric layer (e.g., 655). In an example, when the resonator, such as the series resonator, includes the passivation/tuning dielectric layer (e.g., 655), the front-side dielectric layer of the resonator can include the passivation/tuning dielectric layer (e.g., 655).

For one of the plurality of SXBARs, a back-side dielectric layer (e.g., 760 in FIG. 7) at a back surface of a piezoelectric layer of the one of the plurality of SXBARs may be formed, for example, before the piezoelectric layer is bonded to the substrate at 1815. In an example, another IDT (e.g., dielectric fingers or IDT fingers formed using metal material(s)) is formed on the back surface of the piezoelectric layer of one of the plurality of SXBARs.

In a second variation of the process 1800, one or more cavities are formed in the back side of the device substrate at 1810B. A separate cavity may be formed for each resonator in a filter device. The one or more cavities may be formed using an anisotropic or orientation-dependent dry or wet etch to open holes through the back side of the device substrate to the piezoelectric layer. In this case, the resulting resonator devices may have a cross-section as shown in FIG. 2B.

In a third variation of the process 1800, one or more cavities in the form of recesses in the device substrate may be formed at 1810C by etching the substrate using an etchant introduced through openings in the piezoelectric layer. A separate cavity may be formed for each resonator in a filter device. The one or more cavities formed at 1810C does not penetrate through the device substrate.

Ideally, after the cavities are formed at 1810B or 1810C, most or all of the filter devices on a wafer will meet a set of performance requirements. However, normal process tolerances will result in variations in parameters such as the thicknesses of dielectric layer formed at 1840 and 1850, variations in the thickness and line widths of conductors and IDT fingers formed at 1830, and variations in the thickness of the piezoelectric layer. These variations contribute to deviations of the filter device performance from the set of performance requirements.

To improve the yield of filter devices meeting the performance requirements, frequency tuning may be performed by selectively adjusting the thickness of the passivation/tuning layer deposited over the resonators at 1850. The frequency of a filter device passband can be lowered by adding material to the passivation/tuning layer, and the frequency of the filter device passband can be increased by removing material to the passivation/tuning layer. Typically, the process 1800 is biased to produce filter devices with passbands that are initially lower than a required frequency range but can be tuned to the desired frequency range by removing material from the surface of the passivation/tuning layer.

At 1860, a probe card or other means may be used to make electrical connections with the filter to allow radio frequency (RF) tests and measurements of filter characteristics such as input-output transfer function. Typically, RF measurements are made on all, or a large portion, of the filter devices fabricated simultaneously on a common piezoelectric layer and substrate.

At 1865, global frequency tuning may be performed by removing material from the surface of the passivation/tuning layer using a selective material removal tool such as, for example, a scanning ion mill as previously described. “Global” tuning is performed with a spatial resolution equal to or larger than an individual filter device. The objective of global tuning is to move the passband of each filter device towards a desired frequency range. The test results from 1860 may be processed to generate a global contour map indicating the amount of material to be removed as a function of two-dimensional position on the wafer. The material is then removed in accordance with the contour map using the selective material removal tool.

At 1870, local frequency tuning may be performed in addition to, or instead of, the global frequency tuning performed at 1865. “Local” frequency tuning is performed with a spatial resolution smaller than an individual filter device. The test results from 1860 may be processed to generate a map indicating the amount of material to be removed at each filter device. Local frequency tuning may require the use of a mask to restrict the size of the areas from which material is removed. For example, a first mask may be used to restrict tuning to only shunt resonators, and a second mask may be subsequently used to restrict tuning to only series resonators (or vice versa). This may allow independent tuning of the lower band edge (by tuning shunt resonators) and upper band edge (by tuning series resonators) of the filter devices.

After frequency tuning at 1865 and/or 1870, the filter device is completed at 1875. Actions that may occur at 1875 include forming bonding pads or solder bumps or other means for making connection between the device and external circuitry (if such pads were not formed at 1845); excising individual filter devices from a wafer containing multiple filter devices; other packaging steps; and additional testing. After each filter device is completed, the process ends at 1895.

Throughout this description, the embodiments and examples shown should be considered as examples, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. An acoustic resonator device comprising:
a substrate;
a piezoelectric layer having front and back surfaces;
a front-side dielectric layer at the front surface of the piezoelectric layer;
a back-side dielectric layer at the back surface of the piezoelectric layer that couples the substrate to the back surface of the piezoelectric layer;
a conductor pattern at the front surface of the piezoelectric layer, the conductor pattern including an interdigital transducer (IDT) including a first busbar, a second busbar, and interleaved IDT fingers that include a first IDT finger and an nth IDT finger at opposing ends of the IDT;
a first grating element comprising a grating bar extending from one of the first busbar or the second busbar, the first grating element being adjacent and parallel to the first IDT finger,
wherein an acoustic thickness of the back-side dielectric layer is between 0.5 times an acoustic thickness of the front-side dielectric layer and 1.5 times the acoustic thickness of the front-side dielectric layer.

2. The acoustic resonator device of claim 1, wherein a thickness of the front-side dielectric layer is larger than or equal to a thickness of the IDT fingers.

3. The acoustic resonator device of claim 1, wherein a distance between the grating bar and the first IDT finger is larger than or equal to 0.8×pIDT and is less than 1.0×pIDT, where pIDT is a pitch of the IDT fingers, the distance being measured in a direction that is perpendicular to the IDT fingers and parallel to a surface of the substrate.

4. The acoustic resonator device of claim 1, wherein a width of the grating bar is in a range defined by 0.8 μm and 1.2 μm, the width being measured in a direction that is perpendicular to the IDT fingers and parallel to a surface of the substrate.

5. The acoustic resonator device of claim 1, further comprising a second grating element comprising a second grating bar extending from one of the first busbar or the second busbar, the second grating bar being adjacent and parallel to the nth IDT finger.

6. The acoustic resonator device of claim 5, wherein:
a width of the second grating bar is in a range defined by 0.8 μm and 1.2 μm, the width being measured in a first direction that is perpendicular to the IDT fingers and parallel to a surface of the substrate, and
a distance between the second grating bar and the nth IDT finger is larger than or equal to 0.8×pIDT and less than 1.0×pIDT, where pIDT is a pitch of the IDT fingers, the distance being measured in the first direction.

7. The acoustic resonator device of claim 6, wherein:
the grating bar of the first grating element is connected to a same one of the first busbar or the second busbar as the first IDT finger, and
the second grating bar of the second grating element is connected to a same one of the first busbar or the second busbar as the nth IDT finger.

8. The acoustic resonator device of claim 1, wherein the piezoelectric layer and the IDT are configured such that a radio frequency signal applied to the IDT excites a primary shear acoustic wave in the piezoelectric layer.

9. An acoustic resonator device comprising:
a substrate;
a piezoelectric layer having front and back surfaces;
a front-side dielectric layer at the front surface of the piezoelectric layer;
a back-side dielectric layer at the back surface of the piezoelectric layer that couples the substrate to the back surface of the piezoelectric layer;
a conductor pattern at the front surface of the piezoelectric layer, the conductor pattern including an interdigital transducer (IDT) including a first busbar, a second busbar, and interleaved IDT fingers that include a first IDT finger and an nth IDT finger at opposing ends of the IDT; and
a first grating element comprising a finger extending from one of the first busbar or the second busbar, the first grating element being adjacent and parallel to the first IDT finger and a width of the finger of the first grating element being less than 0.5 μm, the width being measured in a direction that is perpendicular to the IDT fingers,
wherein an acoustic thickness of the back-side dielectric layer is between 0.5 times an acoustic thickness of the front-side dielectric layer and 1.5 times the acoustic thickness of the front-side dielectric layer.

10. The acoustic resonator device of claim 9, wherein a thickness of the front-side dielectric layer is larger than or equal to a thickness of the IDT fingers.

11. The acoustic resonator device of claim 9, wherein:
the first grating element comprises two fingers,
a first of the two fingers of the first grating element is located adjacent to the first IDT finger, and
a second of the two fingers of the first grating element is located on an opposite side of the first of the two fingers of the first grating element with respect to the first IDT finger.

12. The acoustic resonator device of claim 11, wherein a pitch of the two fingers of the first grating element is in a range defined by 0.8×pIDT and 1.5×pIDT, where pIDT is a pitch of the IDT fingers.

13. The acoustic resonator device of claim 9, further comprising a second grating element comprising a finger extending from one of the first busbar or the second busbar, the second grating element being adjacent and parallel to the nth IDT finger.

14. The acoustic resonator device of claim 13, wherein:
the second grating element comprises two fingers,
a first of the two fingers of the second grating element is located adjacent to the nth IDT finger, and
a second of the two fingers of the second grating element is located on an opposite side of the first of the two fingers of the second grating element with respect to the nth IDT finger.

15. The acoustic resonator device of claim 13, wherein:
the finger of the first grating element is connected to a same one of the first busbar or the second busbar as the first IDT finger, and
the finger of the second grating element is connected to a same one of the first busbar or the second busbar as the nth IDT finger.

16. The acoustic resonator device of claim 9, wherein the piezoelectric layer and the IDT are configured such that a radio frequency signal applied to the IDT excites a shear primary acoustic wave within the piezoelectric layer.

17. A bandpass filter, comprising:
a plurality of acoustic resonators comprising one or more series resonators and one or more shunt resonators, wherein:
each of the plurality of acoustic resonators comprises:
a diaphragm comprising a portion a piezoelectric layer that is over a cavity of the respective acoustic resonator, and
an interdigital transducer (IDT) at a surface of the piezoelectric layer, the IDT comprising a first busbar, a second busbar, and interleaved IDT fingers disposed at the respective diaphragm, the IDT fingers including a first IDT finger and an nth IDT finger at opposing ends of the IDT, and
at least one of the one or more shunt resonators further comprises:
a first grating element comprising a grating bar extending from one of the first busbar or the second busbar, the first grating element being adjacent and parallel to the first IDT finger,
a front-side dielectric layer on a front surface of the piezoelectric layer,
a back-side dielectric layer on a back surface of the piezoelectric layer, and
wherein an acoustic thickness of the back-side dielectric layer is between 0.5 times an acoustic thickness of the front-side dielectric layer and 1.5 times the acoustic thickness of the front-side dielectric layer.

18. The bandpass filter of claim 17, wherein:
a distance between the grating bar and the first IDT finger is larger than or equal to 0.8×pIDT and less than 1.0×pIDT, where pIDT is a pitch of the IDT fingers, the distance being measured in a first direction that is perpendicular to a direction in which the IDT fingers extends, and
a width of the grating bar is in a range defined by 0.8 μm and 1.2 μm, the width being measured in the first direction.

19. The bandpass filter of claim 17, wherein the at least one of the one or more shunt resonators further comprises a second grating element comprising a second grating bar extending from one of the first busbar or the second busbar, the second grating bar being adjacent and parallel to the nth IDT finger.

20. The bandpass filter of claim 19, wherein:
a width of the second grating bar is in a range defined by 0.8 μm and 1.2 μm, the width being measured in a first direction that is perpendicular to the IDT fingers and parallel to a surface of the diaphragm, and
a distance between the second grating bar and the nth IDT finger is larger than or equal to 0.8×pIDT and less than 1.0×pIDT, where pIDT is a pitch of the IDT fingers, the distance being measured in the first direction.
